(19) United States
(12) Patent Application Publication
(10) Pub. No.: US 2026/0341335 A1
(43) Pub. Date: Oct. 29, 2026

(54) PHYSICAL LAYER CIRCUIT WITH IMPROVED READ GATING

(71) Applicant: M31 TECHNOLOGY CORPORATION, Hsinchu County (TW)

(72) Inventors: Hsiang-En HUANG, Hsinchu County (TW); Yen-Yin HUANG, Hsinchu County (TW); Sheng-Tsung CHEN, Hsinchu County (TW)

(21) Appl. No.: 19/655,752

(22) Filed: Apr. 23, 2026

(30) Foreign Application Priority Data
Apr. 25, 2025 (TW) 114115761

(51) Int. Cl. G11C 11/4076; G11C 11/4096; H03L 7/081

(52) U.S. Cl. CPC G11C 11/4076; G11C 11/4096; H03L 7/0818

(57) ABSTRACT

A physical layer circuit with improved read gating, includes a delay circuit and a validation-control circuit. In a first mode, corresponding to a first command, the validation-control circuit forms a first reference edge in response to a first strobe edge resulting from a memory, and the delay circuit forms a first internal edge; corresponding to a second command, the validation-control circuit forms a second reference edge in response to a second strobe edge resulting from the memory, the delay circuit forms a second internal edge according to a first time difference between the first internal edge and the first reference edge, and thereby causes a second time difference between the second internal edge and the second reference edge to be shorter than the first time difference, e.g., causes a multiple of the second time difference to be less than the first time difference.

This application claims the benefit of Taiwan application Serial No. 114115761, filed Apr. 25, 2025, the subject matters of which are incorporated herein by reference.

### TECHNICAL FIELD

The present disclosure relates to a physical layer circuit with improved read gating, more specifically, to a physical layer circuit which may access a memory and may rapidly lock to proper read gate timing in a training mode.

### BACKGROUND

A memory is an essential element of a modern electronic apparatus, and a physical layer circuit for accessing the memory is therefore a key point of research and development in modern electrical technology.

### SUMMARY

An aspect of the present disclosure is providing a physical layer circuit (e.g., 10 in FIG. 1) with improved read gating, wherein the physical layer circuit may be coupled to a memory (e.g., 20 in FIG. 1). The physical layer circuit may comprise a delay circuit (e.g., 110 in FIG. 1), a validation-control circuit (e.g., 120 in FIG. 1), a detection circuit (e.g., 130 in FIG. 1), etc. The validation-control circuit may be coupled to the delay circuit and a strobe signal (e.g., DQS in FIG. 1), and the detection circuit may be coupled to the delay circuit and the validation-control circuit. In a first mode (e.g., a training mode), the physical layer circuit may transmit a first command (e.g., cmd1 in FIG. 4a) to the memory; in response to the first command, the memory may sequentially form a plurality of first strobe edges (e.g., edged of signals DQS_t and DQS_c changing from levels vq0 to vq1 between time points tc1 and tcc1, FIG. 4a) in the strobe signal. In response to an earliest one of the first strobe edges (e.g., the one at time point tc1, FIG. 4a), the validation-control circuit may form a first reference edge (e.g., hr1 in FIG. 4a) in a reference signal (e.g., rdgt_ref in FIGS. 1 and 4a). Corresponding to the first command, the delay circuit may form a first internal edge (e.g., hn1 in FIG. 4a) in an internal signal (e.g., rdgt_fbck in FIGS. 1 and 4a), and the detection circuit may detect a first time difference (e.g., dt1 in FIG. 4a) between the first internal edge and the first reference edge, and may cause a control signal (e.g., s_c in FIG. 1) to reflect a detection result of the first time difference. In the first mode, the physical layer circuit may further transmit a second command (e.g., cmd2 in FIG. 4b) to the memory; in response to the second command, the memory may further sequentially form a plurality of second strobe edges (e.g., edges of signals DQS_t and DQS_c changing from levels vq0 to vq1 between time points tc2 and tcc2, FIG. 4b) in the strobe signal. In response to an earliest one of the second strobe edges (e.g., the one at time point tc2, FIG. 4b), the validation-control circuit may further form a second reference edge (e.g., hr2 in FIG. 4b) in the reference signal. Corresponding to the second command, the delay circuit may further form a second internal edge (e.g., hn2 in FIG. 4b) in the internal signal according to the control signal, and may thereby cause a second time difference (e.g., dt2 in FIG. 4b) between the second internal edge and the second reference edge to be shorter than the first time difference.

In an embodiment (e.g., FIGS. 4a and 4b), when the delay circuit causes the second time difference to be shorter than the first time difference, the delay circuit may cause a multiple of the second time difference (e.g., a product of an integer times the second time difference) to be less than the first time difference.

In an embodiment (e.g., FIGS. 4a and 4b), the first time difference may be greater than a multiple of an interface clock period (e.g., T0 in FIG. 1); and, when the delay circuit causes the second time difference to be shorter than the first time difference, the delay circuit may cause the second time difference to be shorter than the interface clock period.

In an embodiment, (e.g., FIG. 5), in a second mode (e.g., a normal mode), the physical layer circuit may further transmit a third command (e.g., cmd[i] in FIG. 5) to the memory; in response to the third command, the memory may form a plurality of third strobe edges (e.g., edges of signals DQS_t and DQS_c changing from levels vq0 to vq1 between time points tz[i] and tzz[i], FIG. 5) in the strobe signal, and may further provide a third data burst (e.g., u[i] in FIG. 5) in a data signal (e.g., DQ in FIGS. 1 and 5); corresponding to the third command, the delay circuit may further form a front gating edge (e.g., hp[i] in FIG. 5) and a back gating edge (e.g., hpp[i] in FIG. 5) in a gating signal (e.g., rd_gt in FIGS. 1 and 5) according to the control signal. According to the gating signal, the validation-control circuit may further select some of the third strobe edges that are between the front gating edge and the back gating edge, and may further reflect a selection result of the third strobe edges in a gated strobe signal (e.g., vDQS in FIGS. 1 and 5). That is, the validation-control circuit may select a subset of the third strobe edges, wherein each third strobe edge in the subset may occur between the front gating edge and the back gating edge. In addition, the physical layer circuit may further comprise a data circuit (e.g., 50 in FIG. 1); the data circuit may be coupled to the validation-control circuit and the data signal, and may sample the data signal according to timing of the gated strobe signal to retrieve the third data burst.

In an embodiment (e.g., FIG. 5), corresponding to the third command, the delay circuit may further form a third internal edge (e.g., hn[i] in FIG. 5) in the internal signal according to the control signal. According to the selection result of the third strobe edges, the validation-control circuit may further form a third reference edge (e.g., hr[i] in FIG. 5) in the reference signal; the detection circuit may further detect a third time difference (e.g., dt[i] in FIG. 5) between the third internal edge and the third reference edge, and may cause the control signal to reflect a detection result of the third time difference. The front gating edge may occur before the third internal edge, and the back gating edge may occur after the third internal edge.

In an embodiment (e.g., FIG. 5), when the validation-control circuit forms the third reference edge in the reference signal according to the selection result of the third strobe edges, the validation-control circuit may form the third reference edge in the reference signal in response to one of the third strobe edges that occurs earliest after the front gating edge (e.g., the one at time point tc[i], FIG. 5).

In an embodiment (e.g., FIG. 1), the physical layer circuit may further comprise a filter circuit (e.g., 140 in FIG. 1) coupled between the detection circuit and the delay circuit. The detection circuit may be configured to generate a detection signal (e.g., s_d in FIG. 1) by detecting the third time difference, and the detection signal may reflect the detection result of the third time difference. The filter circuit may perform signal processing (e.g., filtering operation) on the detection signal to generate the control signal, and may reflect a result of the signal processing (filtering operation) in the control signal.

In an embodiment (e.g., FIG. 5), when the delay circuit forms the third internal edge in the internal signal according to the control signal, the delay circuit may form the internal signal at a third internal edge time point (e.g., tn[i] in FIG. 5). The third internal edge time point may occur after a third origin time point (e.g., to[i] in FIG. 5), and an interval (e.g., dn[i], FIG. 5) between the third origin time point and the third internal edge time point may comprise a coarse tuning duration (e.g., Tn1 in FIG. 5) and a fine tuning duration (e.g., Tn[i] in FIG. 5). The coarse tuning duration may be a multiple of the interface clock period (e.g., T0 in FIG. 5), and the fine tuning duration may be shorter than the interface clock period.

In an embodiment (e.g., FIG. 5), the coarse tuning duration may substantially equal the first time difference minus the second time difference.

In an embodiment (e.g., FIGS. 1 and 5), the control signal may comprise a coarse tuning signal (e.g., s_cr in FIG. 1) and a fine tuning signal (e.g., s_cf in FIG. 1); when the delay circuit forms the third internal edge in the internal signal according to the control signal, the delay circuit may wait for the coarse tuning duration and the fine tuning duration according to the coarse tuning signal and the fine tuning signal respectively, and may form the third internal edge at the third internal edge time point after the coarse tuning duration and the fine tuning duration have elapsed.

In an embodiment (e.g., FIGS. 1 and 5), the delay circuit may comprise a counter (e.g., 1101 in FIG. 1), and the coarse tuning signal may reflect a coarse tuning number (e.g., Nk1 in FIGS. 4a and 4b); the delay circuit may wait for the coarse tuning duration by using the counter to count the coarse tuning number of interface clock periods.

In an embodiment (e.g., FIGS. 4a, 4b and 5), the coarse tuning number may relate to the first time difference.

In an embodiment (e.g., FIG. 1), the delay circuit may comprise a controlled delay line (e.g., 1102 in FIG. 1). The delay circuit may wait for the fine tuning duration by using the controlled delay line to wait for the fine tuning duration, wherein the fine tuning duration may be controlled by the fine tuning signal.

In an embodiment (e.g., FIG. 5), when the detection circuit detects the third time difference between the third internal edge and the third reference edge, operations of the detection circuit may comprise: determining whether the third internal edge occurs before or after the third reference edge.

In an embodiment (e.g., FIG. 4a), when the detection circuit detects the first time difference between the first internal edge and the first reference edge and causes the control signal to reflect the detection result of the first time difference, operations of the detection circuit may comprise: counting a number of interface clock periods within the first time difference, and causing the control signal to reflect a result of the counting.

In an embodiment (e.g., FIGS. 1 and 6a), in a second mode (e.g., a normal mode), the physical layer circuit may further sequentially transmit a third command (e.g., cmd[i] in FIG. 6a) and a fourth command (e.g., cmd[i+1] in FIG. 6a) to the memory; in response to the third command and the fourth command, the memory may further sequentially form a plurality of responding strobe edges (e.g., edges of signals DQS_t and DQS_c changing from levels vq0 to vq1 between time points tz[i] and tzz[i+1], FIG. 6a) in the strobe signal; and, the memory may further provide a third data burst (e.g., u[i] in FIG. 6a) and a fourth data burst (e.g., u[i+1] in FIG. 6a) in the data signal (e.g., DQ in FIGS. 6a and 6b) in response to the third command and the fourth command respectively. When an interval (e.g., Tcc[i] in FIG. 6a) between the third command and the fourth command is greater than a minimal interval (e.g., T_min in FIG. 6a), the delay circuit may further form a third front gating edge, a third back gating edge, a fourth front gating edge and a fourth back gating edge (e.g., hp[i], hpp[i], hp[i+1] and hpp[i+1] in FIG. 6a) in a gating signal (e.g., rd_gt in FIGS. 1 and 6a) according to the control signal (e.g., s_c in FIG. 1); according to the gating signal, the validation-control circuit may further select one or more third gated strobe edges (e.g., strobe edge(s) between time points tp[i] and tpp[i]) and one or more fourth gated strobe edges (e.g., strobe edge(s) between time points tp[i+1] and tpp[i+1]) from the responding strobe edges, wherein each third gated strobe edge may be one of the responding strobe edges, and may occur between the third front gating edge and the third back gating edge; and, each fourth gated strobe edge may be one of the responding strobe edges, and may occur between the fourth front gating edge and the fourth back gating edge. The physical layer circuit may further comprise a data circuit (e.g., 50 in FIG. 1) coupled to the validation-control circuit. The data circuit may sample the data signal according to the one or more third gated strobe edges to retrieve the third data burst, and may sample the data signal according to the one or more fourth gated strobe edges to retrieve the fourth data burst.

In an embodiment (e.g., FIGS. 1 and 6b), in a second mode (e.g., a normal mode), the physical layer circuit may further sequentially transmit a third command (e.g., cmd[i] in FIG. 6b) and a fourth command (cmd[i+1] in FIG. 6b) to the memory; in response to the third command and the fourth command, the memory may further sequentially form a plurality of responding strobe edges (e.g., edges of signals DQS_t and DQS_c changing from levels vq0 to vq1 between time points tz[i] and tzz[i+1], FIG. 6b) in the strobe signal; and, the memory may further provide a third data burst (e.g., u[i] in FIG. 6b) and a fourth data burst (e.g., u[i+1] in FIG. 6b) in a data signal (e.g., DQ in FIG. 6b) in response to the third command and the fourth command respectively. When an interval (e.g., Tcc[i] in FIG. 6b) between the third command and the fourth command is not greater than a minimal interval (e.g., T_min in FIG. 6b), the delay circuit may further form a common front gating edge and a common back gating edge (e.g., hp[i] and hpp[i+1] in FIG. 6b) in a gating signal (e.g., rd_gt in FIGS. 1 and 6b) according to the control signal, and the validation-control circuit may further select one or more gated strobe edges (e.g., strobe edge(s) between time points tp[i] and tpp[i+1]) from the responding strobe edges according to the gating signal, wherein each gated strobe edge may be one of the responding strobe edges, and may occur between the common front gating edge and the common back gating edge. The physical layer circuit may further comprise a data circuit (e.g., 50 in FIG. 1) coupled to the validation-control circuit, and the data circuit may sample the data signal according to the one or more gated strobe edges to retrieve the third data burst and the fourth data burst.

An aspect of the present disclosure is providing a physical layer circuit (e.g., 10 in FIG. 1) with improved read gating, wherein the physical layer circuit may be coupled to a memory (e.g., 20 in FIG. 1). The physical layer circuit may comprise a delay circuit (e.g., 110 in FIG. 1), a validation-control circuit (e.g., 120 in FIG. 1) and a detection circuit (e.g., 130 in FIG. 1). The validation-control circuit may be coupled to the delay circuit and a strobe signal (e.g., DQS_t in FIG. 1), and the detection circuit may be coupled to the delay circuit and the validation-control circuit. The physical layer circuit may transmit a command (e.g., cmd1, cmd2 or cmd[i] in FIGS. 4a, 4b or 5) to the memory, such that the memory may sequentially form a plurality of strobe edges in the strobe signal in response to the command. Corresponding to the command, the delay circuit may form an internal edge (e.g., hn1, hn2 or hn[i] in FIGS. 4a, 4b or 5) in an internal signal (e.g., rdgt_fbck in FIG. 1). In a first mode (e.g., a training mode in FIGS. 4a or 4b), the validation-control circuit may form a reference edge (e.g., hr1 or hr2 in FIGS. 4a or 4b) in a reference signal (e.g., rdgt_ref in FIG. 1) in response to an earliest one of the strobe edges. In a second mode (e.g., a normal mode in FIG. 5), the delay circuit may further form a front gating edge (e.g., hp[i] in FIG. 5) in a gating signal (e.g., rd_gt in FIGS. 1 and 5), and the validation-control circuit may further form the reference edge in the reference signal in response to one of the strobe edges that occurs earliest after the front gating edge (e.g., the strobe edge at time point tc[i], FIG. 5), wherein the front gating edge may occur earlier than the internal edge. The detection circuit may detect a time difference (e.g., dt1, dt2 or dt[i] in FIGS. 4a, 4b or 5) between the internal edge and the reference edge, and may reflect a detection result of the time difference in a detection signal (e.g., s_d in FIG. 1).

In an embodiment (e.g., FIG. 1), the physical layer circuit may further comprise a filter circuit (e.g., 140 in FIG. 1) coupled between the detection circuit and the delay circuit. The filter circuit may perform filtering operation on the detection signal to provide a control signal (e.g., s_c in FIG. 1). When the delay circuit forms the internal edge in the internal signal, the delay circuit may determine, according to the control signal, a time at which the internal edge in the internal signal is formed.

In an embodiment (e.g., FIG. 5), when the delay circuit forms the internal edge in the internal signal, the delay circuit may wait for a coarse tuning duration (e.g., Tn1 in FIG. 5) and a fine tuning duration (e.g., Tn[i] in FIG. 5), and may form the internal edge at an internal edge time point (e.g., tn[i] in FIG. 5) after the coarse tuning duration and the fine tuning duration have elapsed; wherein the coarse tuning duration may an integer multiple of an interface clock period (e.g., T0 in FIGS. 1 and 5), and the fine tuning duration may be shorter than the interface clock period.

An aspect of the present disclosure is providing a method for improving read gating, wherein the method may be implemented by a read gating circuit (e.g., 100 in FIG. 1) in a physical layer circuit (e.g., 10 in FIG. 1), and the physical layer circuit may be coupled to a memory (e.g., 20 in FIG. 1). The method may comprise a plurality of steps. One of the steps may be: when the memory forms a plurality of first strobe edges in a strobe signal (e.g., DQS in FIG. 4a) in response to a first command (e.g., cmd1 in FIG. 4a), forming a first reference edge (e.g., hr1 in FIG. 4a) in a reference signal (e.g., rdgt_ref in FIG. 4a) according to one (e.g., an earliest one) of the first strobe edges. One of the steps may be: corresponding to the first command, forming a first internal edge (e.g., hn1 in FIG. 4a) in an internal signal (e.g., rdgt_fbck in FIGS. 1 and 4a). One of the steps may be: detecting a first time difference (e.g., dt1 in FIG. 4a) between the first internal edge and the first reference edge, and causing a control signal to reflect a detection result of the first time difference. One of the steps may be: when the memory forms a plurality of second strobe edges in the strobe signal in response to a second command (e.g., cmd2 in FIG. 4b), forming a second reference edge (e.g., hr2 in FIG. 4b) in the reference signal according to one (e.g., an earliest one) of the second strobe edges. One of the steps may be: corresponding to the second command, forming a second internal edge (e.g., hn2 in FIG. 4b) in the internal signal according to the control signal, and thereby causing a second time difference (e.g., dt2 in FIG. 4b) between the second internal edge and the second reference edge to be shorter than the first time difference, e.g., causing a multiple of the second time difference (a product of an integer times the second time difference) to be less than the first time difference.

Numerous objects, features and advantages of the present disclosure will be readily apparent upon a reading of the following detailed description of embodiments of the present disclosure when taken in conjunction with the accompanying drawings. However, the drawings employed herein are for the purpose of descriptions and should not be regarded as limiting.

### BRIEF DESCRIPTION OF THE DRAWINGS

The above objects and advantages of the present disclosure will become more readily apparent to those ordinarily skilled in the art after reviewing the following detailed description and accompanying drawings, in which:

FIG. 1 depicts an electronic apparatus according to an embodiment of the present disclosure, wherein the electronic apparatus may comprise a physical layer circuit, a memory, etc., and the physical layer circuit may comprise a read gating circuit, etc.;

FIGS. 2a-2d and 3a-3c depict, by examples, waveform and timing embodiments of related signals when the physical layer circuit in FIG. 1 reads the memory in a normal mode;

FIGS. 4a-4c depict, by examples, waveform and timing embodiments of related signals when the read gating circuit in FIG. 1 operates in a training mode; and

FIGS. 5, 6a and 6b depict, by examples, waveform and timing embodiments of related signals when the read gating circuit in FIG. 1 operates in the normal mode.

### DETAILED DESCRIPTION

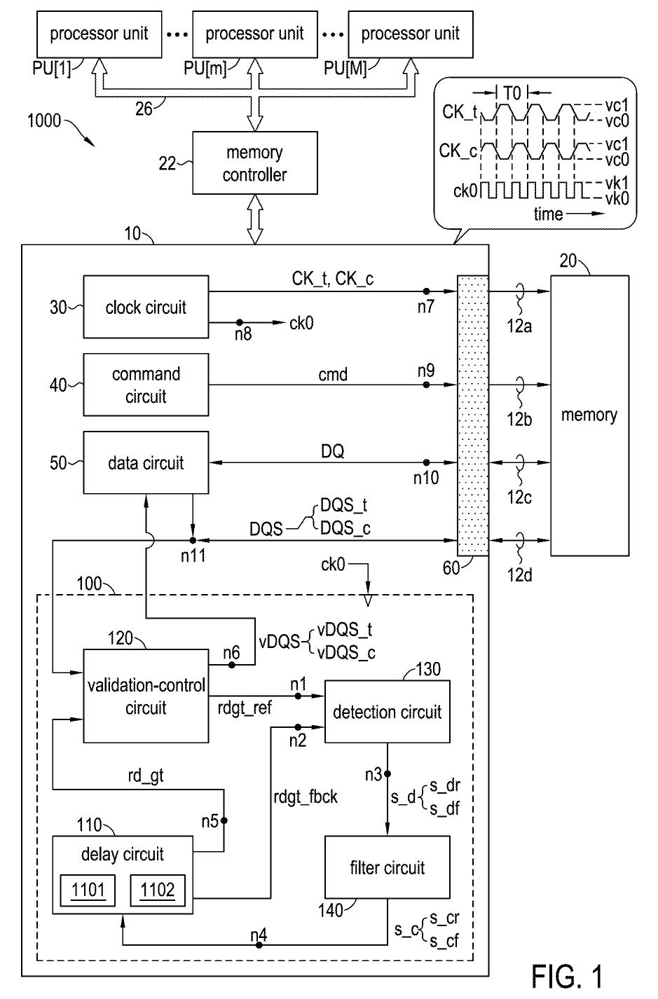

FIG. 1 illustrates an electronic apparatus 1000 according to an embodiment of the present disclosure, wherein the electronic apparatus 1000 may be a smart phone, a tablet computer, a notebook computer, a desktop computer, a smart home appliance or a smart office equipment, etc. The electronic apparatus 1000 may comprise one or more processor units PU[1] to PU[M], a memory controller 22, a physical layer circuit 10 and a memory 20. In the electronic apparatus 1000, the processor units PU[1] to PU[M] may be coupled to the memory controller 22 via a bus 26, and the physical layer circuit 10 may be coupled between the memory controller 22 and the memory 20.

In the electronic apparatus 1000, each processor unit PU[m] (one of PU[1] to PU[M]) may be a central processing unit (or a core processing unit), an application processing unit, a logic processing unit, an arithmetic processing unit, a signal processing unit, a graphic processing unit, a neural processing unit or a peripheral, etc. When the memory 20 operates in a normal mode, the memory 20 may provide a memory space for the processor units PU[1] to PU[M]. In an embodiment, the memory 20 may be a synchronous dynamic random-access memory (SDRAM), e.g., a double data rate (DDR) SDRAM. In an embodiment, the memory 20 may be a memory compliant to industrial standard(s); for example, the industrial standard(s) may be standard(s) formulated by Solid State Technology Association of Joint Electron Device Engineering Council (JEDEC), such as standard(s) related to the fourth generation double data rate (DDR4), the fifth generation double date rate (DDR5), the fourth generation low power double data rate (LPDDR4) and/or the fifth generation low power double data rate (LPDDR5), etc.

The physical layer circuit 10 may comprise a clock circuit 30, a command circuit 40, a data circuit 50 and an input-output circuit 60; to implement the present disclosure, the physical layer circuit 10 may further comprise a read gating circuit 100. In the physical layer circuit 10, the clock circuit 30 may comprise two output terminals respectively coupled to two nodes n7 and n8. The command circuit 40 may comprise an output terminal coupled to a node n9. The data circuit 50 may comprise an input terminal and two connection terminals respectively coupled to three nodes n6, n10 and n11. The input-output circuit 60 may be coupled to the memory 20 via wirings 12a to 12d, and may comprise two input terminals, two output terminals and four connection terminals respectively coupled to the nodes n7 and n9, the wirings 12a and 12b, the wiring 12c, the wiring 12d, the node n10 and the node n11. The read gating circuit 100 may comprise an input terminal and an output terminal respectively coupled to the nodes n11 and n6.

In the physical layer circuit 10, the clock circuit 30 may provide a pair of differential clocks CK_t and CK_c at the node n7, and may provide another clock ck0 at the node n8. As shown in FIG. 1, the clocks CK_t and CK_c may oscillate between two levels vc1 and vc0 with a same oscillation period and opposite phases which may differ by 180 degrees. In an embodiment, the levels vc0 and vc1 may be two levels respectively representing logic 0 and logic 1. An edge of the clock CK_t changing from the levels vc0 to vc1 may be referred to as a significant edge of the clock CK_t, and an interval between two consecutive significant edges of the clock CK_t may be a period T0 of the clock CK_t; for example, the period T0 may represent a time measuring unit nCK in the industrial standard(s). The clock ck0 may oscillate between two levels vk0 and vk1; in an embodiment, an oscillation period of the clock ck0 may be a half of the oscillation period of the clock CK_t. In an embodiment, the levels vk0 and vk1 may be two levels respectively representing logic 0 and logic 1. An edge of the clock ck0 changing from the levels vk0 to vk1 may be referred to as a significant edge of the clock ck0, and each significant edge of the clock CK_t may synchronize (e.g., align) with a corresponding significant edge of the clock ck0. In an embodiment, the physical layer circuit 10 may operate under triggering of the clock ck0, and the input-output circuit 60 may drive the wiring 12a according to timing of the clocks CK_t and CK_c, such that the memory 20 may operate according to timing of the clocks CK_t and CK_c. In the physical layer circuit 10, the clocks CK_t and CK_c may be referred to as interface clocks, the period T0 may be referred to as an interface clock period, and the clock ck0 may be referred to as an internal clock.

In the physical layer circuit 10, the command circuit 40 may provide a signal cmd at the node n9, and the input-output circuit 60 may drive the wiring 12b according to the signal cmd. When the processor unit PU[m] requests to store write-in data to the memory 20, the memory controller 22 may control the physical layer circuit 10 according to the request; under control of the memory controller 22, the command circuit 40 in the physical layer circuit 10 may cause the memory 20 to remain in a normal mode, and may form a corresponding write command (not depicted) in the signal cmd; the data circuit 50 may drive a signal DQ at the node n10 according to contents of the write-in data, and may drive a signal DQS at the node n11 according to timing of the write-in data. According to the signal cmd, the input-output circuit 60 may drive the wiring 12b, so the write command may be transmitted to the memory 20. The driving of the data circuit 50 at the node n10 may cause the input-output circuit 60 to correspondingly drive the wiring 12c, and may therefore cause the memory 20 to receive a write-in data signal (not depicted); the driving of the data circuit 50 at the node n11 may cause the input-output circuit 60 to corresponding drive the wiring 12d, and may therefore cause the memory 20 to obtain timing of the write-in data in the write-in data signal. According to the timing of the write-in data, the memory 20 may sample the write-in data signal to retrieve the write-in data, and may store the write-in data according to the write command.

On the other hand, when the processor unit PU[m] requests to read the memory 20, the memory controller 22 may control the physical layer circuit 10 according to the request; under control of the memory controller 22, the command circuit 40 in the physical layer circuit 10 may cause the memory 20 to remain in the normal mode, and may form a corresponding read command (not depicted) in the signal cmd. According to the signal cmd, the input-output circuit 60 may drive the wiring 12b, so the read command may be transmitted to the memory 20. In response to the read command, the memory 20 may read corresponding stored data (not depicted), may drive the wiring 12c according to contents of the stored data, and may drive the wiring 12d according to timing of the stored data. The driving of the memory 20 at the wiring 12c may cause the input-output circuit 60 to correspondingly drive the signal DQ at the node n10, and may therefore cause the data circuit 50 to receive a stored data signal (not depicted); the driving of the memory 20 at the wiring 12d may cause the input-output circuit 60 to correspondingly drive the signal DQS at the node n11, and may therefore cause the read gating circuit 100 to obtain timing of the stored data in the stored data signal. The read gating circuit 100 may reflect the timing of the stored data in a signal vDQS at the node n6; according to the signal vDQS, the data circuit 50 may sample the stored data signal to retrieve the stored data, and the memory controller 22 may transmit the retrieved stored data to the processor unit PU[m].

In the physical layer circuit 10, the signal cmd may be referred to as a command signal, the signal DQ may be referred to as a data signal, the signal DQS may be referred to as a strobe signal, and the signal vDQS may be referred to as a gated strobe signal. In an embodiment, the signal DQS may comprise a pair of differential signals DQS_t and DQS_c. In an embodiment, the signal vDQS may comprise a pair of differential signals vDQS_t and vDQS_c.

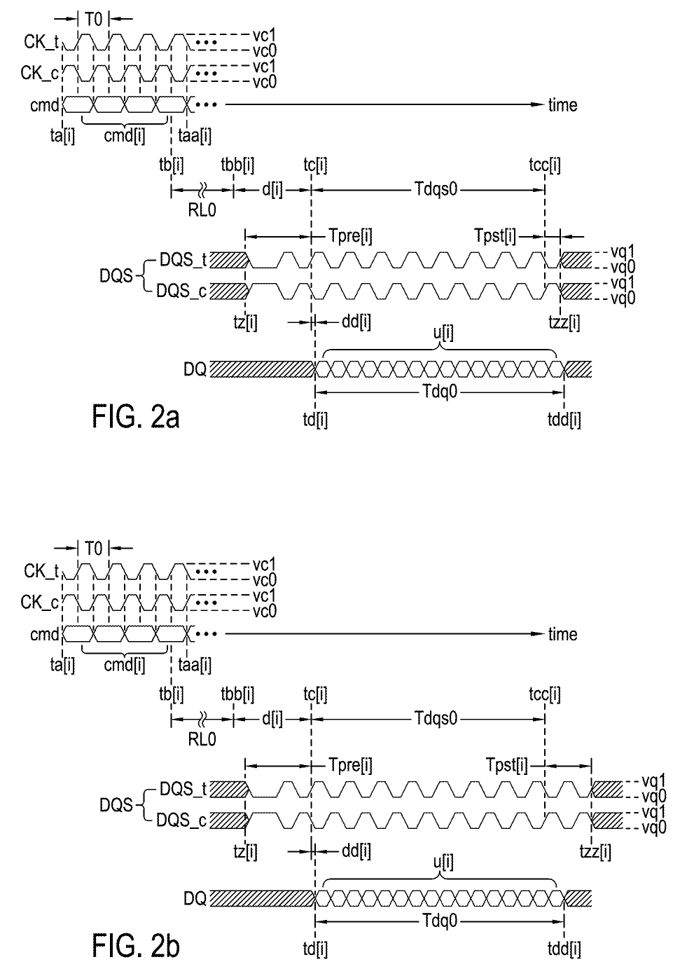

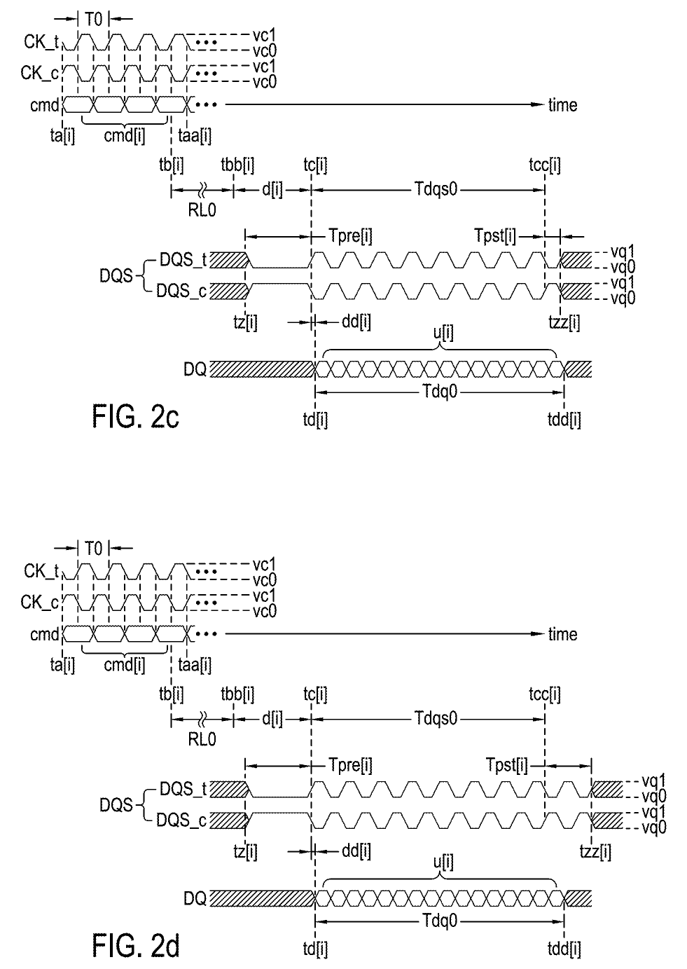

Continuing FIGS. 1, 2a-2d illustrate, by examples, waveform and timing embodiments of related signals when the physical layer circuit 10 reads the memory 20 in the normal mode. As shown in FIG. 2a, when reading the memory 20 in the normal mode, the command circuit 40 may form a command cmd[i], e.g., a read command, in the signal cmd between two time points ta[i] and taa[i] In an embodiment, an interval between the time points ta[i] and taa[i] may equal to four of the period T0. The time points ta[i] and taa[i] may respectively be at two different significant edges of the clock CK_c (edges of the clock CK_c changing from the levels vc0 to vc1). The input-output circuit 60 in the physical layer circuit 10 may transmit the command cmd[i] to the memory 20 via the wiring 12b. In response to the command cmd[i], the memory 20 may read corresponding stored data (not depicted), may drive the wiring 12c according to contents of the stored data, and may drive the wiring 12d according to timing of the stored data.

The driving of the memory 20 at the wiring 12d may cause waveforms of the signals DQS_t and DQS_c to be unambiguous between two time points tz[i] and tzz[i], and may therefore sequentially form a plurality of strobe edges in the signals DQS_t and DQS_c. Each strobe edge in the signal DQS_t may be an edge of the DQS_t changing from a level vq0 to another level vq1, and each strobe edge in the signal DQS_c may be an edge of the signal DQS_c changing from the levels vq0 to vq1. In an embodiment, the levels vq0 and vq1 may be two levels respectively representing logic 0 and logic 1. Before and after the memory 20 drives the wiring 12d in response to the command cmd[i], the memory 20 may not drive the wiring 12d, so the waveforms of the signals DQS_t and DQS_c may be ambiguous before the time point tz[i] and after the time point tzz[i], and are therefore shown shaded in FIG. 2a.

The driving of the memory 20 at the wiring 12c may cause a waveform of the signal DQ to be unambiguous between two time points td[i] and tdd[i], and may therefore provide a data burst u[i], i.e., the stored data read out by the memory 20, in the signal DQ. The data burst u[i] may comprise a plurality of serial bits, and the number of the bits may be represented by a parameter BL (burst length, not depicted) in the industrial standard(s); for example, the parameter BL may be an even number. The data burst u[i] may last for a duration Tdq0; that is, an interval between the time points td[i] and tdd[i] may equal the duration Tdq0; in an embodiment, the duration Tdq0 may equal a half of the parameter BL times the period T0 (i.e., Tdq0 = (BL/2)*T0). Before and after the memory 20 drives the wiring 12c in response to the command cmd[i], the memory 20 may not drive the wiring 12c, so the waveform of the signal DQ may be ambiguous before the time point td[i] and after the time point tdd[i], and is therefore shown shaded in FIG. 2a.

Between two time points tc[i] and tcc[i], the strobe edges in the signals DQS_t and DQS_c may respectively correspond to timing of the bits in the data burst u[i]; for example, the strobe edges in the signal DQS_t between the time points tc[i] and tcc[i] may respectively correspond to odd (first, third, fifth, etc.) bits of the data burst u[i], and the strobe edges in the signal DQS_c between the time points tc[i] and tcc[i] may respectively correspond to even (second, fourth, sixth, etc.) bits of the data burst u[i]. The time point tc[i] may be at a certain strobe edge of the signal DQS_t, the time point tcc[i] may be at a certain strobe edge of the signal DQS_c, and an interval between the time points tc[i] and tcc[i] may equal a duration Tdqs0, e.g., the period T0 times a value (BL/2-0.5). Between the time points tc[i] and tcc[i], the number of the strobe edges in the signal DQS_t may equal a half of the parameter BL, and the number of the strobe edges in the signal DQS_c may also equal a half of the parameter BL. Because routines of the wirings 12c and 12d may possibly be different, the time point tc[i] may be earlier than the time point td[i], and an interval between the two time points may equal a duration dd[i], wherein the duration dd[i] may represent a parameter tDQSQ (DQS-DQ skew, not depicted) in the industrial standard(s).

Because the transmission of the command cmd[i] and the response of the memory 20 may take some time, the time point tc[i] may be later than a time point tb[i] during the command cmd[i], wherein the time point tb[i] may be at a last significant edge of the clock CK_t before the command cmd[i] ends (at the time point taa[i]). There may be another time point tbb[i] between the time points tb[i] and tc[i], an interval between the time points tb[i] and tbb[i] may equal a duration RL0, and an interval between the time points tbb[i] and tc[i] may equal a duration d[i], wherein the duration RL0 may equal the period T0 times a parameter RL (read latency, not depicted) in the industrial standard(s). The duration d[i] may represent another parameter tDQSCK (DQS output access time from CK_t/CK_c, not depicted) in the industrial standard(s).

As shown in FIG. 2a, the time point tz[i] may be earlier than the time point tc[i] by a duration Tpre[i]. The duration Tpre[i] may be a preamble attached to the signals DQS_t and DQS_c by the memory 20, wherein the duration Tpre[i] may represent a parameter tRPRE (read preamble, not depicted) in the industrial standard(s). Also, as shown in FIG. 2a, the time point tcc[i] may be earlier than the time point tzz[i] by a duration Tpst[i]. The duration Tpst[i] may be a postamble attached to the signals DQS_t and DQS_c by the memory 20, wherein the duration Tpst[i] may represent a parameter tRPST (read postamble, not depicted) in the industrial standard(s).

In the example of FIG. 2a, the preamble of the signals DQS_t and DQS_c during the preamble duration Tpre[i] may be of a "toggle" format in the industrial standard(s), and the postamble during the postamble duration Tpst[i] may be of a "0.5nCK" format in the industrial standard(s); that is, the duration Tpst[i] may equal a half of the period T0. The preamble and postamble of the signals DQS_t and DQS_c may be of other formats, as shown in FIGS. 2b-2d. In the example of FIG. 2b, the preamble of the signals DQS_t and DQS_c during the preamble duration Tpre[i] may be of the "toggle" format, and the postamble during the postamble duration Tpst[i] may be of a "1.5nCK" format in the industrial standard(s); that is, the duration Tpst[i] may equal one and a half of the period T0, i.e., the postamble duration Tpst[i] of the signals DQS_t and DQS_c may be longer than a half of the period T0 by one of the period T0. In the example of FIG. 2c, the preamble of the signals DQS_t and DQS_c during the preamble duration Tpre[i] may be of a "static" format in the industrial standard(s), and the postamble during the postamble duration Tpst[i] may be of the "0.5nCK" format. In the example of FIG. 2d, the preamble of the signals DQS_t and DQS_c during the preamble duration Tpre[i] may be of the "static" format, and the postamble during the postamble duration may be of the "1.5nCK" format.

As previously described, the strobe edges in the signals DQS_t and DQS_c between the time points tc[i] and tcc[i] may correspond to timing of the bits in the data burst u[i], and may therefore be considered as effective (valid) strobe edges; when the data circuit 50 in the physical layer circuit 10 (FIG. 1) samples the signal DQ to retrieve the stored data sent back to the physical layer circuit 10 by the memory 20, the data circuit 50 may sample according to these effective strobe edges. Among the effective strobe edges in the signals DQS_t and DQS_c between the time points tc[i] and tcc[i], the strobe edge occurring at the time point tc[i] may be the earliest effective strobe edge. On the other hand, as shown in FIGS. 2a-2d, the signal(s) DQS_t and/or DQS_c may also have strobe edge(s) during the preamble duration Tpre[i] and/or the postamble duration Tpst[i]; however, if the data circuit 50 in the physical layer circuit 10 samples the signal DQ mistakenly according to the strobe edge(s) in the preamble duration Tpre[i] and/or the postamble duration Tpst[i], the data circuit 50 would sample the ambiguous portion (shown shaded) of the signal DQ, and would consequently fail to correctly retrieve the stored data of the memory 20. Therefore, the strobe edge(s) occurring during the preamble and the postamble of the signals DQS_t and DQS_t may be considered as ineffective (invalid) strobe edge(s). The read gating circuit 100 in the physical layer circuit 10 may remove the preamble and the postamble of the signals DQS_t and DQS_c, and may reflect a result of the removal in the signals vDQS_t and vDQS_c, so the data circuit 50 may correctly sample the signal DQ according to the signals vDQS_t and vDQS_c.

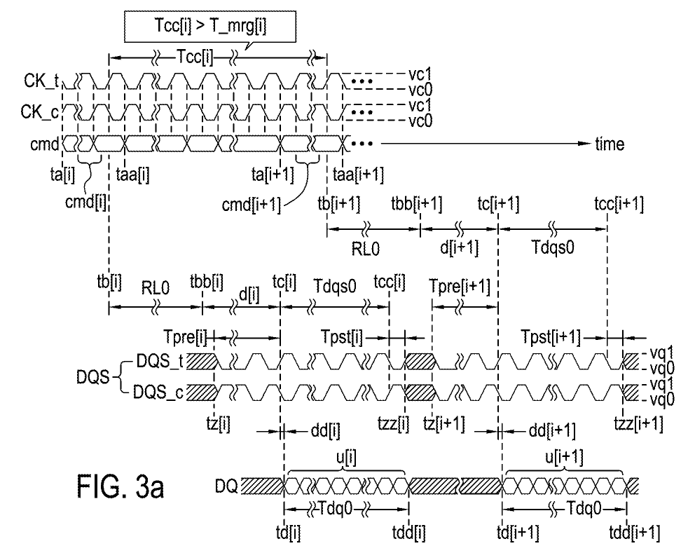

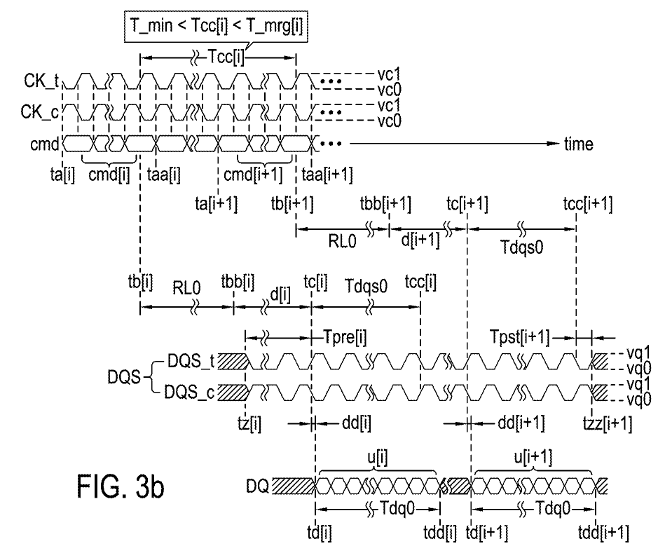

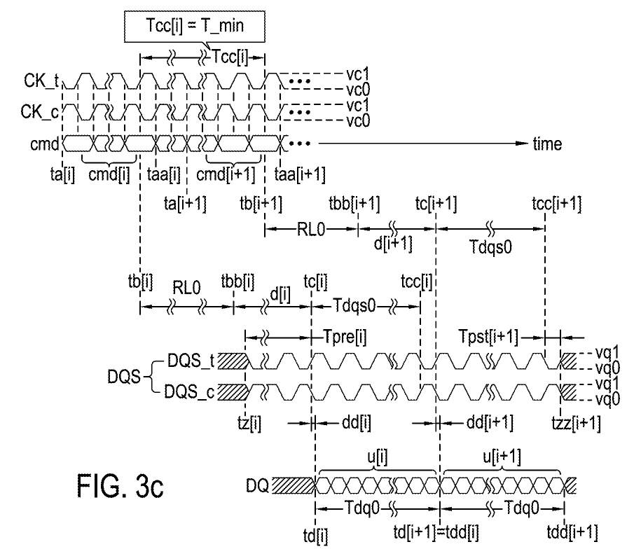

When the processor units PU[1] to PU[M] access the memory 20 frequently, the physical layer circuit 10 may transmit corresponding commands to the memory 20 frequently, so an interval between two consecutive commands will be shortened. Continuing FIGS. 1 and 2a-2d, 3- 3c illustrate, by examples, waveform and timing embodiments of related signals when the physical layer circuit 10 accesses the memory 20 in the normal mode by two consecutive commands cmd[i] and cmd[i+1]. As shown in FIG. 3a, in response to an access request (e.g., a read request) of the processor units PU[1] to PU[M], the command circuit 40 may form the command cmd[i] (e.g., a read command) between the time points ta[i] and taa[i] in the signal cmd; in response to a subsequent access request (e.g., a next read request) of the processor units PU[1] to PU[M], the command circuit 40 may form a consecutive command cmd[i+1] (e.g., a consecutive read command) in the signal cmd between another two time points ta[i+1] and taa[i+1] after the time point taa[i].

As described when referring to FIGS. 2a-2d, in response to the command cmd[i], the memory 20 may drive the wirings 12c and 12d; the driving of the memory 20 at the wiring 12d may cause the waveforms of the signals DQS_t and DQS_c to be unambiguous between the time points tz[i] and tzz[i] to form the strobe edges, and the driving of the memory 20 at the wiring 12c may provide the data burst u[i] in the signal DQ between the time points td[i] and tdd[i]. The time point tz[i] may be earlier than the time point tc[i] by the preamble duration Tpre[i], the time point tzz[i] may be later than the time point tcc[i] by the postamble duration Tpst[i], and the time point tcc[i] may be later than the time point tc[i] by the duration Tdqs0. Regarding the signal DQS, the time point tc[i] may be later than the time point tbb[i] by the duration d[i], the time point tbb[i] may be later than the time point tb[i] by the duration RL0, and the time point tb[i] may be at the last significant edge of the clock CK_t right before the command cmd[i] ends (at the time point taa[i]). Regarding the signal DQ, the time point td[i] may be later than the time point tc[i] by the duration dd[i], and the time point tdd[i] may be later than the time point td[i] by the duration Tdq0.

Similarly, in response to the command cmd[i+1], the memory 20 may drive the wirings 12c and 12d; the driving of the memory 20 at the wiring 12d may cause the waveforms of the signal DQS_t and DQS_c to be unambiguous between two time point tz[i+1] and tzz[i+1] to form a plurality of strobe edges, and the driving of the memory 20 at the wiring 12c may provide a data burst u[i+1] in the signal DQ between another two time points td[i+1] and tdd[i+1]. Regarding to the signal DQS, the time point tz[i+1] may be earlier than a time point tc[i+1] by a preamble duration Tpre[i+1], the time point tzz[i+1] may be later than another time point tcc[i+1] by a postamble duration Tpst[i+1], the time point tcc[i+1] may be later than the time point tc[i+1] by the duration Tdqs0, the time point tc[i+1] may be later than a time point tbb[i+1] by a duration d[i+1], the time point tbb[i+1] may be later than another time point tb[i+1] by the duration RL0, and the time point tb[i+1] may be at a last significant edge of the clock CK_t before the command cmd[i+1] ends (at the time point taa[i+1]). Regarding the signal DQ, the time point td[i+1] may be later than the time point tc[i+1] by a duration dd[i+1], and the time point tdd[i+1] may be later than the time point td[i+1] by the duration Tdq0.

An interval between the time point tb[i+1] of the succeeding command cmd[i+1] and the time point tb[i] of the preceding command cmd[i] may equal a duration Tcc[i], and the duration Tcc[i] may represent a parameter tCCD (CAS-to-CAS delay, not depicted) in the industrial standard(s). As read requests are more frequent, the time points tb[i] and tb[i+1] of the consecutive commands cmd[i] and cmd[i+1] will be closer, and the duration Tcc[i] between the time points tb[i] and tb[i+1] will be shorter; as a result, the time point tzz[i] (end of the postamble duration Tpst[i]) and the time point tz[i+1] (start of the preamble duration Tpre[i+1]) related to the signal DQS_t and DQS_c will be closer. As shown in FIG. 3a, since the time point tzz[i] may equal (tb[i] + RL0 + d[i] + Tdqs0 + Tpst[i]) and the time point tz[i+1] may equal (tb[i+1] + RL0 + d[i+1] - Tpre[i+1]), a difference (tz[i+1] - tzz[i]) between the time points tzz[i] and tz[i+1] may equal (tb[i+1] - tb[i] + d[i+1] -d[i] - Tpre[i+1] - Tdqs0 - Tpst[i]); in addition, since (tb[i+1] - tb[i]) may equal the duration Tcc[i] and a difference between the durations d[i+1] and d[i] may be relatively small and thus be neglectable, the difference (tz[i+1] - tzz[i]) between the time points tzz[i] and tz[i+1] may be further simplified to (Tcc[i] - Tdqs0 - Tpre[i+1] - Tpst[i]). It is therefore understood that, when duration Tcc[i] equals a sum of the durations Tpre[i+1], Tdqs0 and Tpst[i], the time points tz[i+1] and tzz[i] may coincide. For convenience of discussion, the sum of the durations Tpre[i+1], Tdqs0 and Tpst[i] may be defined as a duration T_mrg[i], as shown in FIG. 3a.

In the example of FIG. 3a, the duration Tcc[i] between the commands cmd[i] and cmd[i+1] is longer than the duration T_mrg[i], and is therefore long enough to cause the time point tzz[i] to be earlier than the time point tz[i+1]. However, if the commands cmd[i] and cmd[i+1] are closer and thus the duration Tcc[i] is shorter than the duration T_mrg[i], the memory 20 may merge the postamble corresponding to the command cmd[i] and the preamble corresponding to the command cmd[i+1], as shown in FIG. 3b. In FIG. 3b, the memory 20 may keep on driving the wiring 12d when responding to the commands cmd[i] and cmd[i+1], so the waveforms of the signals DQS_t and DQS_c may remain unambiguous between the time points tcc[i] (start of the postamble corresponding to the command cmd[i]) and the time point tc[i+1] (end of the preamble corresponding to the command cmd[i+1]) to merge the postamble and the preamble respectively corresponding to the commands cmd[i] and cmd[i+1]. On the other hand, in the example of FIG. 3a, the waveforms of the signals DQS_t and DQS_c may not always remain unambiguous between the time points tcc[i] and tc[i+1]. In the example of FIG. 3a, the memory 20 may not merge the postamble and the preamble respectively corresponding to the commands cmd[i] and cmd[i+1]; after responding to the command cmd[i], the memory 20 may not drive the wiring 20d for a while, so the waveforms of the signals DQS_t and DQS_c may be ambiguous (shown shaded) between the time points tzz[i] and tz[i+1].

In the example of FIG. 3b, when the preamble and the postamble respectively corresponding to the two consecutive commands are merged, what the waveforms of the signals DQS_t and DQS_c between the time points tcc[i] and tc[i+1] will be may relate to the format of the preamble, the format of the postamble and the duration Tcc[i], and may not be further described since related details may be found in the industrial standard(s). In the example of FIG. 3b, the unambiguous waveforms of the signals DQS_t and DQS_c between the time points tcc[i] and tc[i+1] may form one or more strobe edges, but the one or strobe edges will be ineffective strobe edge(s).

From FIG. 3b, it is understood that, since the end time point tdd[i] of the data burst u[i] may equal (tb[i] + RL0 + d[i] + dd[i] + Tdq0) and the start time point td[i+1] of the data burst u[i+1] may equal (tb[i+1] + RL0 + d[i+1] +dd[i+1]), a difference (td[i+1] - tdd[i]) between the time points tdd[i] and td[i+1] may equal (tb[i+1] - tb[i] + d[i+1] - d[i] + dd[i+1] - dd[i] - Tdq0). Because a difference (dd[i+1] - dd[i]) between the durations dd[i+1] and dd[i] may be relatively small and may be neglectable, the difference (td[i+1] - tdd[i]) between the time points tdd[i] and td[i+1] may be further simplified to (Tcc[i] - Tdq0). It is then understood that, when the duration Tcc[i] equals the duration Tdq0, the time points tdd[i] and td[i+1] may coincide. For convenience of discussion, the duration Tdq0 may be defined as a duration T_min, and the duration T_min may be referred to as a minimal interval.

In the example of FIG. 3b, the duration Tcc[i] between the commands cmd[i] and cmd[i+1] is longer than the duration T_min, and is therefore long enough to cause the time point tdd[i] at which the data burst u[i] ends to be earlier than the time point td[i+1] at which the data burst u[i+1] starts. However, if the commands cmd[i] and cmd[i+1] are closer so the duration Tcc[i] equals the duration T_min, the time points tdd[i] and td[i+1] may coincide, the memory 20 may seamlessly serialize the data bursts u[i] and u[i+1] respectively corresponding to the commands cmd[i] and cmd[i+1] in the signal DQ, and may remove the postamble and the preamble respectively corresponding to the commands cmd[i] and cmd[i+1] in the signals DQS_t and DQS_c, as shown in FIG. 3c. In FIG. 3c, the memory 20 may keep on driving the wiring 12d when responding to the commands cmd[i] and cmd[i+1], so the waveforms of the signals DQS_t and DQS_c may remain unambiguous between the time point tz[i] (start of the preamble corresponding to the command cmd[i]) and the time point tzz[i+1] (end of the postamble corresponding to the command cmd[i+1]. Between the time point tc[i] (end of the preamble corresponding to the command cmd[i]) and the time point tcc[i+1] (start of the postamble corresponding to the command cmd[i+1]), each strobe edge in the signals DQS_t and DQS_c may be an effective strobe edge, and may correspond to one bit of the data burst u[i] or u[i+1]; that is, the postamble corresponding to the command cmd[i] and the preamble corresponding to the command cmd[i+1] may disappear.

Regardless of whether the postamble and preamble of consecutive two commands are not merged (FIG. 3a), are merged (FIG. 3b) or disappear (FIG. 3c), the read gating circuit 100 (FIG. 1) of the present disclosure is capable of removing the ineffective strobe edge(s) in the signals DQS_t and DQS_c, and reflecting the effective strobe edges of the signals DQS_t and DQS_c in the signals vDQS_t and vDQS_c. As shown in FIG. 1, the read gating circuit 100 may comprise a delay circuit 110, a validation-control circuit 120, a detection circuit 130 and a filter circuit 140. The delay circuit 110 may comprise an input terminal and two output terminals coupled to three nodes n4, n5 and n2, respectively. The validation-control circuit 120 may comprise two input terminals and two output terminals coupled to the node n5, the node n11 and another two nodes n1 and n6, respectively. The detection circuit 130 may comprise two input terminals and an output terminal coupled to the node n1, the node n2 and another node n3, respectively. The filter circuit 140 may comprise an input terminal and an output terminal coupled to the nodes n3 and n4, respectively. The delay circuit 110 may respectively provide two signals rd_gt and rdgt_fbck at the nodes n5 and n2; the validation-control circuit 120 may provide a signal rdgt_ref at the node n1, and may provide the signal vDQS (comprising the signals vDQS_t and vDQS_c) at the node n6. The detection circuit 130 may provide a signal s_d at the node n3, and the filter circuit 140 may provide a signal s_c at the node n4. The signal rdgt_ref may be referred to as a reference signal, the signal rdgt_fbck may be referred to as an internal signal, the signal rd_gt may be referred to as a gating signal, and the signals s_d and s_c may be referred to as a detection signal and a control signal, respectively.

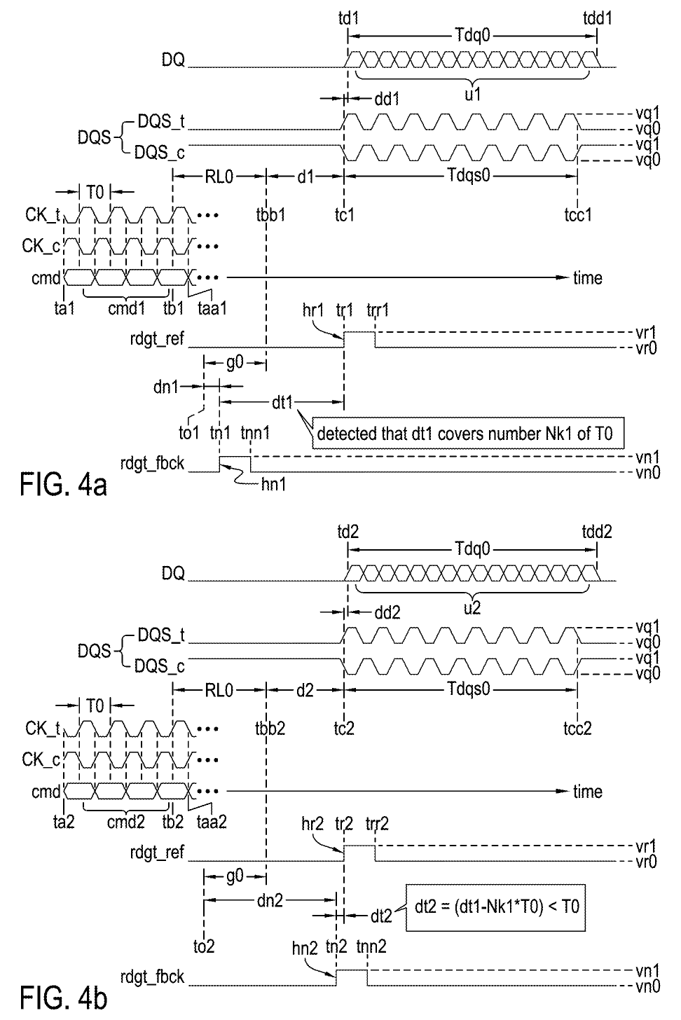

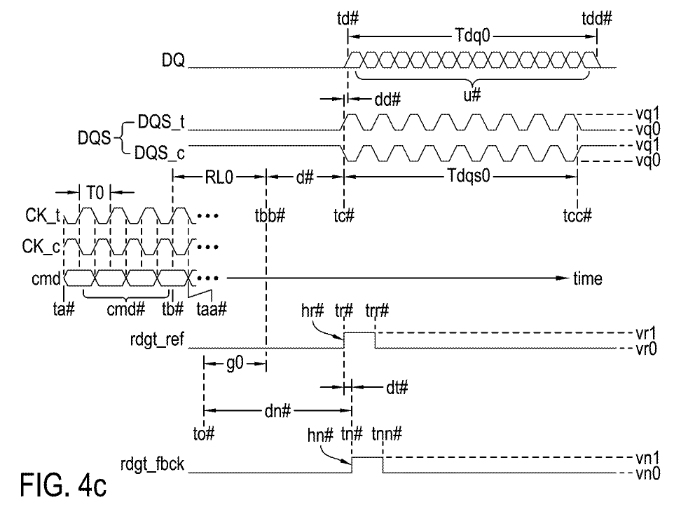

To implement the present disclosure, before the memory 20 operates in the normal mode, the physical layer circuit 10 may cause the memory 20 to enter a training mode, e.g., a read preamble training mode in the industrial standard(s). Continuing FIGS. 1, 4a-4c illustrate, by examples, waveform and timing embodiments of related signals when the read gating circuit 100 operates in the training mode. After causing the memory 20 to operate in the training mode, the command circuit 40 in the physical layer circuit 10 may issue a command cmd1 to the memory 20 between two time points ta1 and taa1, as shown in FIG. 4a. Before the time point ta1, when the memory 20 is already in the training mode, the memory 20 may drive the wiring 12d to keep the signals DQS_t and DQS_c at the levels vq0 and vq1 respectively, and may drive the wiring 12c to keep the signal DQ at a fixed level. Afterward, in response to the command cmd1 between the time points ta1 and taa1, the memory 20 may change the driving at the wirings 12c and 12d; the driving of the memory 20 at the wiring 12d may therefore sequentially form a plurality of strobe edges (edges changing from the levels vq0 to vq1) in the signals DQS_t and DQS_c between two time points tc1 and tcc1, and the driving of the memory 20 at the wiring 12c may provide a data burst u1 in the signal DQ between two time points td1 and tdd1. As shown in FIG. 4a, the time point tcc1 may be later than the time point tc1 by the duration Tdqs0, the time point tc1 may be later than a time point tbb1 by a duration d1, the time point tbb1 may be later than another time point tb1 by the duration RL0, and the time point tb1 may be at a last significant edge of the clock CK_t before the time point taa1. The time point td1 may be later than the time point tc1 by a duration dd1, and the time point tdd1 may be later than the time point td1 by the duration Tdq0.

As shown in FIG. 4a, in response to an earliest strobe edge in the signal DQS_t (i.e., the strobe edge at the time point tc1), the validation-control circuit 120 may cause the signal rdgt_ref to change from a level vr0 to another level vr1 at a time point tr1, and may thereby form a significant edge hr1 in the signal rdgt_ref. In an embodiment, the time point tr1 may approximate or coincide with the time point tc1, and the levels vr0 and vr1 may be two levels respectively representing logic 0 and logic 1. At another time point trr1 after the time point tr1, the validation-control circuit 120 may cause the signal rdgt_ref to change back from the levels vr1 to vr0, and may thereby form a reverse edge in the signal rdgt_ref. In an embodiment, an interval between the time points tr1 and trr1 may equal a predetermined duration, such as the period T0.

Corresponding to the command cmd1, the delay circuit 110 may cause the signal rdgt_fbck to change from a level vn0 to another level vn1 at a time point tn1, and may thereby form a significant edge hn1 in the signal rdgt_fbck. In an embodiment, the time point tn1 may be later than a time point to1 by a duration dn1, and the time point to1 may be earlier than the time point tbb1 by a duration g0. In an embodiment, the duration g0 may equal a predetermined number (e.g., four) times the period T0. In an embodiment, the levels vn0 and vn1 may be two levels representing logic 0 and logic 1, respectively. At another time point tnn1 after the time point tn1, the delay circuit 110 may cause the signal rdgt_fbck to change back from the levels vn1 to vn0, and may thereby form a reverse edge in the signal rdgt_fbck. In an embodiment, an interval between the time points tn1 and tnn1 may equal a predetermined duration, such as the period T0.

In some embodiments, the time point tn1 of the significant edge hn1 may equal the time point tb1 plus one or more clock periods (with one said clock period being the period of the interface clock or the internal clock, for example). In some embodiments, the time point tn1 of the significant edge hn1 may be between the time points tb1 and tc1. For example, the delay circuit 110 may determine when the time point tn1 of the significant edge hn1 may be according to read latency (or the duration RL0), wherein the time point tn1 may equal the time point tbb1 minus one or more clock periods (with one said clock period being the period of the interface clock or the internal clock, for example), or may equal the time point tbb1 plus one or more clock periods (with one said clock period being the period of the interface clock or the internal clock, for example).

In the read gating circuit 100, the detection circuit 130 may detect a time difference dt1 between the significant edges hn1 and hr1 (i.e., an interval between the time points tn1 and tr1), and may reflect a detection result of the time difference dt1 in the signal s_d (FIG. 1). In an embodiment, when the detection circuit 130 detects the time difference dt1 and reflects the detection result of the time difference dt1 in the signal s_d, operations of the detection circuit 130 may comprise: counting the number of periods T0 within the time difference dt1, and reflecting a result of the counting in the signal s_d; a number Nk1 shown in FIG. 4a may represent that the detection circuit 130 counts to find that the time difference dt1 covers the number Nk1 of the periods T0. The filter circuit 140 (FIG. 1) may perform signal processing (e.g., filtering operation) on the signal s_d, and may reflect a result of the signal process in the signal s_c. In the training mode, the memory 20 may keep on driving the wirings 12d and 12c after responding to the command cmd1, may therefore cause the signals DQS_t and DQS_c to respectively remain at the levels vq0 and vq1, and may cause the signal DQ to remain at a fixed level.

As shown in FIG. 4b, when the memory 20 is still in the training mode after the command cmd1 ends at the time point taa1, the command circuit 40 in the physical layer circuit 10 may issue another command cmd2 to the memory 20 between two time points ta2 and taa2, wherein the time point ta2 may be later than the time point taa1. In response to the command cmd2 between the time points ta2 and taa2, the memory 20 may change the driving at the wirings 12c and 12d; the driving of the memory 20 at the wiring 12d may therefore sequentially form a plurality of strobe edges in the signals DQS_t and DQS_c between two time points tc2 and tcc2, and the drive of the memory 20 at the wiring 12c may provide a data burst u2 in the signal DQ between two time points td2 and tdd2. As shown in FIG. 4b, the time point tcc2 may be later than the time point tc2 by the duration Tdqs0, the time point tc2 may be later than a time point tbb2 by a duration d2, the time point tbb2 may be later than another time point tb2 by the duration RL0, and the time point tb2 may be at a last significant edge of the clock CK_t before the time point taa2. The time point td2 may be later than the time point tc2 by a duration dd2, and the time point tdd2 may be later than the time point td2 by the duration Tdq0.

As shown in FIG. 4b, in response to an earliest strobe edge in the signal DQS_t (i.e., the strobe edge at the time point tc2), the validation-control circuit 120 may cause the signal rdgt_ref to change from the levels vr0 to vr1 at a time point tr2, and may thereby form a significant edge hr2 in the signal rdgt_ref. In an embodiment, the time point tr2 may approximate or coincide with the time point tc2. At another time point trr2 after the time point tr2, the validation-control circuit 120 may cause the signal rdgt_ref to change back from the levels vr1 to vr0. In an embodiment, an interval between the time points tr2 and trr2 may equal the interval between the time points tr1 and trr1.

Corresponding to the command cmd2, the delay circuit 110 may cause the signal rdgt_fbck to change from the levels vn0 to vn1 at a time point tn2, and may thereby form a significant edge hn2 in the signal rdgt_fbck. In an embodiment, the time point tn2 may be later than a time point to2 by a duration dn2, and the time point to2 may be earlier than the time point tbb2 by the duration g0. At another time point tnn2 after the time point tn2, the delay circuit 110 may cause the signal rdgt_fbck to change back from the levels vn1 to vn0, and may thereby form a reverse edge in the signal rdgt_fbck. In an embodiment, an interval between the time points tn2 and tnn2 may equal the interval between the time points tn1 and tnn1. The detection circuit 130 may detect a time difference dt2 between the significant edges hn2 and hr2 (i.e., an interval between the time points tn2 and tr2), and may reflect a detection result of the time difference dt2 in the signal s_d. The filter circuit 140 may perform signal processing (e.g., filtering operation) on the signal s_d, and may reflect a result of the signal process in the signal s_c. In the training mode, the memory 20 may keep on driving the wiring 12d and 12c after responding to the command cmd2, and may therefore cause the signal DQS_t and DQS_c to respectively remain at the levels vq0 and vq1, and may cause the signal DQ to remain at a fixed level.

In FIGS. 4a and 4b, each of the time points to1 and to2 may be referred to as an origin time point, and an interval between the time points to2 and tb2 may equal an interval between the time points to1 and tb1; in other words, the time point to1, like the time point tb1, may represent timing of the command cmd1; similarly, the time points to2 and tb2 may represent timing of the command cmd2. The significant edge hr1 and hr2 formed by the validation-control circuit 120 in the signal rdgt_ref may be referred to as reference edges, and the time points tr1 and tr2 of the significant edges hr1 and hr2 may reflect actual timing of the corresponding strobe edges formed when the memory 20 responds to the commands cmd1 and cmd2 (e.g., actual time points when the earliest strobe edges occur), respectively. On the other hand, the significant edges hn1 and hn2 formed by the delay circuit 110 in the signal rdgt_fbck may be referred to as internal edges; the delay circuit 110 may estimate expected timing of the corresponding strobe edges formed when the memory 20 responds to the commands cmd1 and cmd2 (e.g., expected time points when the earliest strobe edges occur), and may reflect the expected timing by the time points tn1 and tn2 of the significant edges hn1 and hn2. Thus, for the command cmd1 (FIG. 4a), the time difference dt1 (FIG. 4a) between the time points tn1 and tr1 may reflect an error between the expected timing (estimated by the delay circuit 110) and the actual timing of the strobe edges related to the command cmd1; for the command cmd2 (FIG. 4b), the time difference dt2 (FIG. 4b) between the time points tn2 and tr2 may reflect an error between the expected timing (estimated by the delay circuit 110) and the actual timing of the strobe edges related to the command cmd2.

In FIG. 4a, the delay circuit 110 may control the duration dn1 to control how long the time point tn1 of the significant edge hn1 will lag behind the time point tb1 of the command cmd1; similarly, in FIG. 4b, the delay circuit 110 may also control the duration dn2 to control how long the time point tn2 of the significant edge hn2 will lag behind the time point tb2 of the command cmd2. In FIG. 4b, the delay circuit 110 may control the duration dn2 according to the signal s_c. As described earlier, in an embodiment, the detection circuit 130 may already count to find the number Nk1 and reflect the number Nk1 in the signal s_d earlier in FIG. 4a, and the filter circuit 140 may already reflect the signal s_d in the signal s_c; thus, in FIG. 4b, when the delay circuit 110 controls the duration dn2 according to the signal s_c, the delay circuit 110 may control the duration dn2 according to the number Nk1, e.g., may cause the duration dn2 to equal the duration dn1 plus the number Nk1 times the period T0. Hence, the time difference dt2 (FIG. 4b) between the time points tn2 and tr2 may be significantly shorter than the time difference dt1 (FIG. 4a). While the time difference dt1 in FIG. 4a may be greater (longer) than the number Nk1 times the period T0, the time difference dt2 in FIG. 4b may be less (shorter) than the period T0 after the delay circuit 110 adjusts the duration dn2 according to the number Nk1; in other words, the delay circuit 110 may cause a multiple (e.g., the number Nk1) of the time difference dt2 to be less than the time difference dt1. That is, by experience of the two commands cmd1 and cmd2, the expected timing of the strobe edges estimated by the delay circuit 110 for a command may rapidly converge to the actual timing of the strobe edges formed when the memory 20 responds to the command.

As shown in FIG. 4c, after the command cmd2 ends, the physical layer circuit 10 may continue to transmit one or more succeeding commands to the memory 20 in the training mode, such as a command cmd# between two time points time point ta# and taa#, wherein the time point ta# may be later than the time point taa2. In response to the command cmd#, the memory 20 may sequentially form a plurality of strobe edges in the signals DQS_t and DQS_c between two time points tc# and tcc#, and may provide a data burst u# in the signal DQ between another two time points td# and tdd#. The time point tcc# may be later than the time point tc# by the duration Tdqs0, the time point tc# may be later than a time point tbb# by a duration d#, the time point tbb# may be later than another time point tb# by the duration RL0, and the time point tb# may be at a last significant edge of the clock CK_t before the time point taa#. The time point td# may be later than the time point tc# by a duration dd#, and the time point tdd# may be later than the time point td# by the duration Tdq0.

In response to an earliest strobe edge in the signal DQS at the time point tc#, the validation-control circuit 120 may form a significant edge hr# (an edge changing from the levels vr0 to vr1) in the signal rdgt_ref at a time point tr# to reflect actual timing of the strobe edges formed when the memory 20 responds to the command cmd#, and the delay circuit 110 may estimate expected timing of the strobe edges formed when the memory 20 responds to the command cmd# (e.g., a time point when the earliest one of the strobe edges is expected to occur) according to the signal s_c, and may form a significant edge hn# (an edge changing from the levels vn0 to vn1) in the signal rdgt_fbck at a time point tn# according to the expected timing, wherein the time point tn# may be later than another time point to# by a duration dn#, and the time point to# may be earlier than the time point tbb# by the duration g0. The detection circuit 130 may detect a time difference dt# between the significant edges hn# and hr#, and may reflect a detection result of the time difference dt# in the signal s_d; the filter circuit 140 may perform signal processing (e.g., filtering operation) on the signal s_d, and may reflect a result of the signal process in the signal s_c. By the signal s_c fed back to the delay circuit 110 via the detection circuit 130 and the filter circuit 140, when the delay circuit 110 estimates expected timing of other strobe edges formed in response to another subsequent command (not depicted) in the training mode, the delay circuit 110 may perform fine tuning on the estimation, so the expected timing may approximate the actual timing closer.

Similar to FIGS. 4a and 4b, the time point to# in FIG. 4c may be referred to as an origin time point, and the significant edges hr# and hn# may be referred to as a reference edge and an internal edge, respectively. When the delay circuit 110 estimates the expected timing of the strobe edges corresponding to the command cmd# according to the signal s_c and forms the significant edge hn# according to the expected timing, the delay circuit 110 may determine the duration dn# according to the signal s_c, and may therefore determine when the time point tn# will locate in time axis. At a time point tnn# after the time point tn#, the delay circuit 120 may cause the signal rdgt_fbck to change back from the levels vn1 to vn0; at a time point trr# after the time point tr#, the validation-control circuit 120 may cause the signal rdgt_ref to change back from the levels vr1 to vr0. An interval between the time points tr# and trr# may equal the interval between the time points tr1 and trr1, and an interval between the time points tn# and tnn# may equal the interval between the time points tn1 and tnn1. In the training mode, the memory 20 may keep on driving the wirings 12d and 12c after responding to the command cmd#, may thereby keep the signal DQS_t and DQS_c at the levels vq0 and vq1 respectively, and may keep the signal DQ at a fixed level. However, when the memory 20 enters the normal mode (e.g., FIGS. 2a to 2d and 3a-3c) after the training mode (e.g., FIGS. 4a-4c) ends, the memory 20 will drive the wirings 12d and 12c to cause the signals DQS and DQ to have unambiguous waveforms only when responding to commands, instead of always driving the wirings 12d and 12c; as shown in the examples of FIGS. 2a-2d and 3a-3c, the waveforms of the signals DQS and DQ may be ambiguous (shown shaded) when the memory 20 does not drive the wirings 12d and 12c.

In an embodiment, the signal s_d may comprise two signals s_dr and s_df (FIG. 1), the signal s_dr may reflect the number of periods T0 within the time difference dt# between the significant edges hn# and hr#, and the signal s_df may reflect whether the significant edge hn# is earlier or later than the significant edge hr#. For example, in an embodiment, the signal s_df may reflect/indicate, by a first logic value or a second logic value, whether the significant edge hn# in the signal rdgt_fbck is earlier or later than the significant edge hr# in the signal rdgt_ref.

In an embodiment, the signal s_c provided by the filter circuit 140 may comprise two signal s_cr and s_cf (FIG. 1), and the filter circuit 140 may further comprise different signal paths (not depicted) to perform different signal processes on the signals s_dr and s_df in the signal s_d to provide the signals s_cr and s_cf, respectively. For example, the signal processing performed on the signal s_df by the filter circuit 140 may be accumulating the number of times the first logic value and the second logic value appear in the signal s_df; if a number of times the first logic value appears is much greater than a number of times the second logic value appears (e.g., a difference between the former and the latter is greater than a predefined first threshold count), the filter circuit 140 may reflect an extending message (not depicted) in the signal s_cf; after the delay circuit 110 receives the extending message in the signal s_c, when the delay circuit 110 forms a subsequent significant edge hn#' (not depicted) in the signal rdgt_fbck corresponding to a subsequent command cmd#' (not depicted), the delay circuit 110 may extend an interval between the command cmd#' and the significant edge hn#'. On the other hand, if the number of times the second logic value appears is much greater than the number of times the first logic value appears (e.g., a difference of the former and the latter is greater than a predefined second threshold count), the filter circuit 140 may reflect a shortening message (not depicted) in the signal s_cf; after the delay circuit 110 receives the shortening message in the signal s_c, when the delay circuit 110 forms the significant edge hn#' in the signal rdgt_fbck corresponding to the command cmd#', the delay circuit 110 may shorten the interval between the command cmd#' and the significant edge hn#'.

In the training mode, when the memory 20 responds to the command cmd1, cmd2 and cmd#, the memory 20 may not attach the preamble and the postamble in the signal DQS_t and DQS_c; that is, in the training mode, all the strobe edges formed by the memory 20 in the signals DQS_t and DQS_c may be effective strobe edges, and may reflect timing of the bits in the data bursts u1, u2 and u#.

After experiencing several commands during the training mode, the delay circuit 110 may lock each significant edge of the signal rdgt_fbck to a corresponding significant edge of the signal rdgt_ref, e.g., may substantially align a significant edge of the signal rdgt_fbck with a corresponding significant edge of the signal rdgt_ref; achieving such lock may represent that the expected timing of the strobe edges estimated by the read gating circuit 100 for a command already closely approximate the actual timing of the strobe edges formed in response to the command. In an embodiment, after several commands, if the number of times the first logic value appears in the signal s_df and the number of times the second logic value appears in the signal s_df are of minor difference, and the signal value of the signal s_dr remains unchanged, then the read gating circuit 100 may determine that the lock is achieved.

After achieving the lock in the training mode, the physical layer circuit 10 may cause the memory 20 to enter the normal mode to be accessed by the processor units PU[1] to PU[M]. Continuing FIGS. 1 and 2a-2d, 5 illustrates, by an example, waveform and timing embodiments of related signal when the read gating circuit 100 operates in the normal mode. As described earlier by referring to FIGS. 2a-2d, in response to the command cmd[i], the memory 20 may sequentially form the strobe edges in the signals DQS_t and DQS_c between the time points tz[i] and tzz[i], and may provide the data burst u[i] in the signal DQ between the time points td[i] and tdd[i]. The strobe edges between the time points tc[i] and tcc[i] may be effective strobe edges.

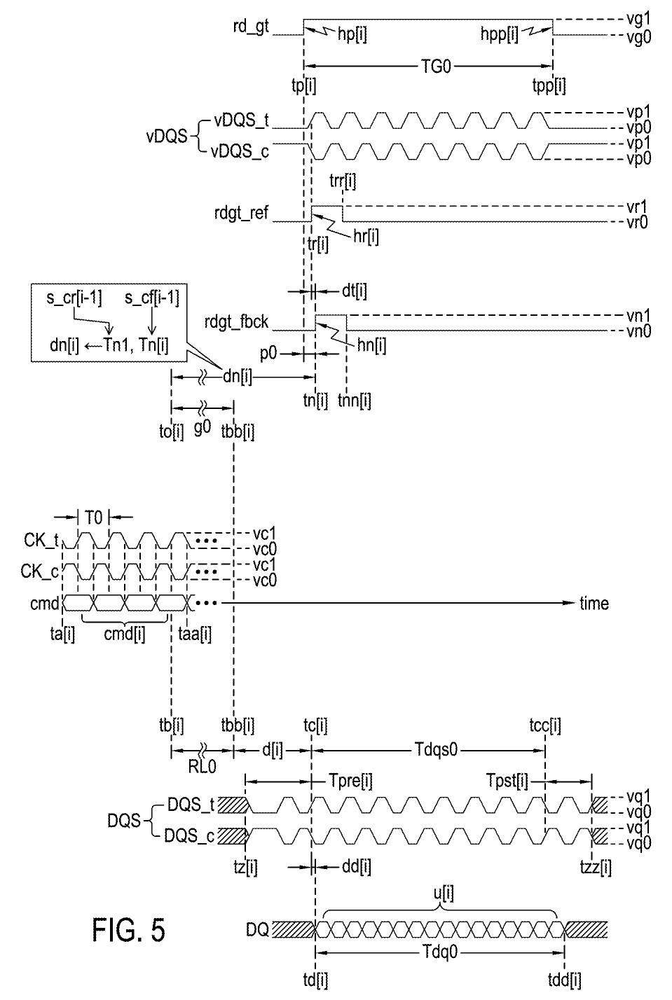

As shown in FIG. 5, corresponding to the command cmd[i], the delay circuit 110 in the read gating circuit 100 may cause the signal rdgt_fbck to change from the levels vn0 to vn1 at a time point tn[i] to form a significant edge hn[i], and may further cause the signal rdgt_fbck to change back from the levels vn1 to vn0 at another time point tnn[i]. In addition, corresponding to the command cmd[i], the delay circuit 110 may further cause the signal rd_gt to change from a level vg0 to another level vg1 to form an edge hp[i] at a time point tp[i], and may also cause the signal rd_gt to change back from the levels vg1 to vg0 to form another edge hpp[i] at another time point tpp[i]. The levels vg0 and vg1 may be two levels respectively representing logic 0 and logic 1, the time point tn[i] may be later than a time point to[i] by a duration dn[i], and the time point to[i] may be earlier than the time point tbb[i] by the duration g0. The time point tnn[i] may be later than the time point tn[i] by an interval equal to the interval between the time points tn1 and tnn1 (FIG. 4a). The time point tp[i] may be earlier than the time point tn[i] by a duration p0, and the time point tpp[i] may be later than the time point tp[i] by a duration TG0. In an embodiment, the duration p0 may equal a predetermined value times the period T0, e.g., a quarter of the period T0. In an embodiment, the duration TG0 may equal the duration Tdq0.

Similar to the time points to1, to2 and to# in FIGS. 4a-4c, the time point to[i] in FIG. 5 may be referred to as an origin time point, and an interval between the time points to[i] and tb[i] may equal the interval between the time points to1 and tb1, so the time points to[i] and tb[i] may represent timing of the command cmd[i]. Similar to the significant edges hn1, hn2 and hn# in FIGS. 4a-4c, the significant edge hn[i] in FIG. 5 may be referred to as an internal edge. In addition, the edges hp[i] and hpp[i] formed by the delay circuit 110 in the signal rd_gt may be respectively referred to as a front gating edge and a back gating edge.

Similar to the training mode in FIGS. 4a-4c, in the normal mode shown in FIG. 5, when the memory 20 forms the strobe edges in the signal DQS_t and DQS_c in response to the command cmd[i], the delay circuit 110 may estimate expected timing of the effective strobe edges among the strobe edges according to the signal s_c, and may reflect the expected timing by the time point tn[i] of the significant edge hn[i], the time point tp[i] of the edge hp[i] and the time point tpp[i] of the edge hpp[i]; for example, the time point tn[i] may reflect a time point when an earliest one of the effective strobe edges is expected to occur, the time point tp[i] before the time point tn[i] may reflect a time point between expected time points of the earliest effective strobe edge and a preceding ineffective strobe edge, and the time point tpp[i] later than the time point tn[i] may reflect a time point between expected time points of a last effective strobe edge and a succeeding ineffective strobe edge.

According to the edges hp[i] and hpp[i] of the signal rd_gt, the validation-control circuit 120 may select one or more gated strobe edges from the strobe edges in the signals DQS_t and DQS_c, and may reflect a selection result in the signals vDQS_t and vDQS_c. For example, in an embodiment, the validation-control circuit 120 may select the strobe edges between the time points tp[i] and tpp[i] in the signals DQS_t and DQS_c as the gated strobe edges, and may, in response to the gated strobe edges, form corresponding strobe edges in the signals vDQS_t and vDQS_c (e.g., by causing the signals vDQS_t and vDQS_c to change from a level vp0 to another level vp1, wherein the levels vp0 and vp1 may be two levels respectively representing logic 0 and logic 1). The gated strobe edges selected from the signals DQS_t and DQS_c by the validation-control circuit 120 may reflect the effective strobe edges in the signals DQS_t and DQS_c; that is, the selection performed by the validation-control circuit 120 according to the rd_gt may remove ineffective strobe edge(s) of the preamble and the postamble, and may reflect the effective strobe edges of the signals DQS_t and DQS_c in the signals vDQS_t and vDQS_c, respectively. Hence, when the data circuit 50 in the physical layer circuit 10 samples the signal DQ according to timing (the strobe edges) of the signals vDQS_t and vDQS_c, the data circuit 50 may correctly retrieve each bit of the data burst u[i], and may prevent incorrect sampling during the ambiguous portion (shown shaded) of the signal DQ.

In addition, when the validation-control circuit 120 selects the gated strobe edges from the signals DQS_t and DQS_c according to the signal rd_gt, the validation-control circuit 120 may further, in response to an earliest gated strobe edge (i.e., an earliest strobe edges after the edge hp[i], at the time point tc[i]), cause the signal rdgt_ref to change from the levels vr0 to vr1 at a time point tr[i] to form a significant edge hr[i] in the signal rdgt_ref. Similar to the significant edges hr1, hr2 and hr# in FIGS. 4a-4c, the significant edge hr[i] in FIG. 5 may be referred to as a reference edge, the time point tr[i] when the significant edge hr[i] occurs may reflect an actual time point at which an earliest effective strobe edge occurs.

Similar to previously described by referring to FIGS. 4a-4c, in the normal mode of FIG. 5, the detection circuit 130 may detect a time difference dt[i] between the time points tn[i] and tr[i], and may reflect a detection result of the time difference dt[i] in the signal s_d; the filter circuit 140 may perform signal processing (e.g., filtering operation) on the signal s_d, and may reflect a result of the signal process in the signal s_c. Similar to previously described by referring to FIGS. 4a-4c, in the normal mode of FIG. 5, the signal s_d may comprise the signals s_dr and s_df (FIG. 1), and the signal s_c may comprise the signals s_cr and signal s_cf (FIG. 1). In an embodiment, when the detection circuit 130 detects and obtains the time difference dt[i] between the time points tr[i] and tn[i], the detection circuit 130 may update a signal value of the signal s_dr from a previous signal value s_dr[i-1] (not depicted) to a current signal value s_dr[i] (not depicted), may update a signal of the signal s_df from a previous signal value s_df[i-1] (not depicted) to a current signal value s_df[i] (not depicted), and may thereby reflect the detection result of the time difference dt[i] by the signal values of the signals s_dr[i] and s_df[i]. In an embodiment, when the detection circuit 130 detects the time difference dt[i], the detection circuit 130 may count the number of periods T0 within the time difference dt[i], and may determine whether the significant edge hn[i] occur before or after the significant edge hr[i]; when the detection circuit 130 reflects the detection result in the signal s_d, the detection circuit 130 may reflect how many periods T0 the time difference dt[i] covers by the signal value s_dr[i], and may reflect/indicate, by the signal value s_df[i], whether the significant edge hn[i] is earlier or later than the significant edge hr[i]. In an embodiment, when the filter circuit 140 performs the signal process on the updated signal s_d and reflects the result of the signal process in the signal s_c, the filter circuit 140 may update a signal value of the signal s_cr from a previous signal value s_cr[i-1] to a current signal value s_cr[i], may update a signal value of the signal s_cf from a previous signal value s_cr[i-1] to a current signal value s_cr[i], and may thereby reflect the result of the signal process of the updated signal s_d by the signal values s_cr[i] and s_cf[i].

In an embodiment, operations of the detection circuit 130 and the filter circuit 140 in the training mode and operations of the detection circuit 130 and the filter circuit 140 in the normal mode may be similar. For example, in the normal mode, the detection circuit 130 may reflect/indicate whether the significant edge hn[i] is earlier or later than the significant edge hr[i] by setting the signal value s_df[i] to the first logic value or the second logic value. If the signal value s_df[i] equals the first logic value, the signal process performed on the signal s_df by the filter circuit 140 may cause the signal value s_cf[i] to reflect that a first logic value appearance count (i.e., the number of times the first logic value appears) increases by one comparing to the first logic value appearance count reflected by the signal value s_cf[i-1]; if the signal value s_df[i] equals the second logic value, the signal process performed on the signal s_df by the filter circuit 140 may cause the signal value s_cf[i] to reflect that a second logic value appearance count (i.e., the number of times the second logic value appears) increases by one comparing to the second logic value appearance count reflected by the signal value s_cf[i-1].

The delay circuit 110 may control the duration dn[i] according to the signal s_c, and may thereby control where the time point tn[i] (and time points tp[i] and tpp[i]) will locate in time axis. As shown in FIG. 5, in an embodiment, the duration dn[i] may comprise two durations Tn1 and Tn[i]; when the delay circuit 110 forms the significant edge hn[i] in the signal rdgt_fbck, the delay circuit 110 may, from the time point to[i], wait for the durations Tn1 and Tn[i] respectively according to the previous signal value s_cr[i-1] of the signal s_cr and the previous signal value s_cf[i-1] of the signal s_cf, and may form the significant edge hn[i] at the time point tn[i] after the waiting ends (e.g., the durations Tn1 and Tn[i] have elapsed). In an embodiment, the duration Tn1 may equal one or more periods T0, and the duration Tn[i] may be shorter than the period T0. In an embodiment, the duration Tn1 may equal the time difference dt1 in FIG. 4a minus the time difference dt2 in FIG. 4b. In an embodiment, the signal value s_cr[i-1] of the signal s_cr may reflect the number Nk1 (FIG. 4a), and the delay circuit 110 may further comprise a counter 1101 (FIG. 1); the delay circuit 110 may wait for the duration Tn1 by using the counter 1101 to count the number Nk1 of periods T0. As previously described by referring to FIG. 4a, when the detection circuit 130 detects the time difference dt1, the detection circuit 130 may count the number of periods T0 within the time difference dt1, and may reflect the resultant number Nk1 in the signal s_cr. That is, the signal s_cr in the normal mode may remain equal to the signal s_cr obtained in the training mode.

In an embodiment, the delay circuit 110 may further comprise a controlled delay line 1102 which may be controlled by the signal s_cf; the delay circuit 110 may wait for the duration Tn[i] by using the controlled delay line 1102 to wait for the duration Tn[i], and the duration Tn[i] may be controlled by the signal value s_cf[i-1] of the signal s_cf. In the read gating circuit 100, the signals s_cr and s_cf may be referred to as a coarse tuning signal and a fine tuning signal respectively, the durations Tn1 and Tn[i] may be referred to as a coarse tuning duration and a fine tuning duration respectively, and the number Nk1 may be referred to as a coarse tuning number.

As previously described, when the memory 20 responds to the command cmd1, cmd2 or cmd# in the training mode as shown in FIGS. 4a, 4b or 4c, the memory 20 may form multiple strobe edges in the signal DQS between the time points tc1 and tcc1, the time points tc2 and tcc2 or the time points tc# and tcc#, and these strobe edges may be effective strobe edges. On the other hand, when the memory 20 responds to the command cmd[i] in the normal mode as shown in FIG. 5, the memory 20 may also form multiple strobe edges in the signal DQS between the time points tz[i] and tzz[i]; however, among these strobe edges, only the strobe edges between the time points tc[i] and tcc[i] may be effective strobe edges, while other strobe edge(s) may be ineffective strobe edge(s); that is, the strobe edge(s) between the time points tz[i] and tc[i] and the strobe edge(s) between the time points tcc[i] to tzz[i] may be ineffective strobe edge(s). Though the memory 20 may form ineffective strobe edges during the preamble and/or the postamble of the signal DQS in the normal mode, an interval between the time points tb# and tc# (as well as an interval between the time points tb1 and tc1, and an interval between the time points tb2 and tc2) in the training mode may reflect an interval between the time points tb[i] and tc[i] in the normal mode, wherein the time points tb1, tb2, tb# and tb[i] may respectively represent timing of the commands cmd1, cmd2, cmd# and cmd[i], and the time points tc1, tc2, tc# and tc[i] may respectively represent timing of the effective strobe edges. That is, an interval between each command and its corresponding strobe edges in the training mode (e.g., the interval between the time points tb1 and tc1, the interval between the time points tb2 and tc2 or the interval between the time points tb# and tc#) may reflect an interval between each command and its corresponding effective strobe edges in the normal mode (e.g., the interval between the time points tb[i] and tc[i]).

In the training mode (e.g., FIGS. 4a-4c), when the delay circuit 110 already achieves lock between expected timing and actual timing of the strobe edges formed in response to each command, the delay circuit 110 may already be able to correctly estimate an interval between each command and its corresponding strobe edges; later, in the normal mode (e.g., FIG. 5), when the delay circuit 110 estimates expected timing of the effective strobe edges formed in response to each command cmd[i], the delay circuit 110 may estimate the expected timing of the effective strobe edges for each command cmd[i] according to the lock previously achieved in the training mode (e.g., according to the signal s_cr at the training mode lock), and may reflect the expected timing by the duration dn[i], the significant edge hn[i] and the signal rd_gt; according to timing of the signal rd_gt, the validation-control circuit 120 may select the gated strobe edges from the signal DQS to reflect the effective strobe edges between the time points tc[i] and tcc[i], and may reflect the selection result in the signal vDQS and the significant edge hr[i]. The detection circuit 130 may detect the time difference dt[i] between the significant edges hn[i] and hr[i]. Via feedback from the detection circuit 130 and the filter circuit 140 to the delay circuit 110, the delay circuit 110 may fine-tune when estimating expected timing of effective strobe edges formed in response to a subsequent command, and may thereby cause the expected timing of the effective strobe edges to remain locked with actual timing of the effective strobe edges.

When the memory 20 responds to the command cmd[i] in the normal mode, the actual timing of the effective strobe edges may dynamically drift since the duration d[i] between the time points tbb[i] and tc[i] may dynamically vary due to variation of bias voltage and/or temperature. However, when the memory 20 responds to a plurality of sequential commands in the normal mode, because the delay circuit 110 may, according to the feedback of the detection circuit 130 and the filter circuit 140, keep on fine-tuning estimation of expected timing of effective strobe edges resulting from the sequential commands, the expected timing of the effective strobe edges estimated by the delay circuit 110 for the sequential commands may therefore remain locked with actual timing of the effective strobe edges even if the actual timing of the effective strobe edges drifts.

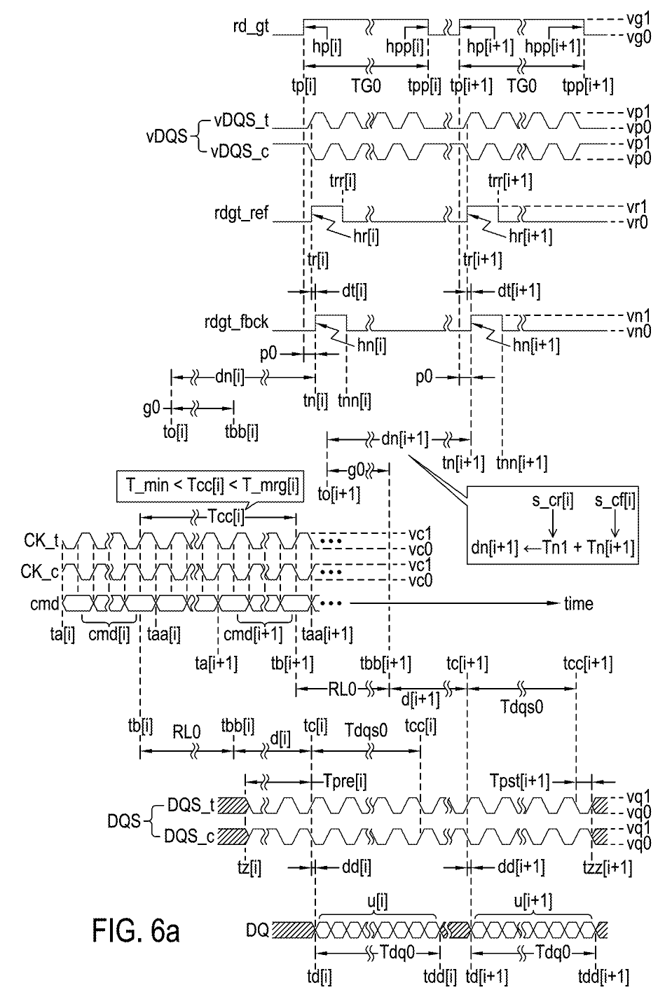

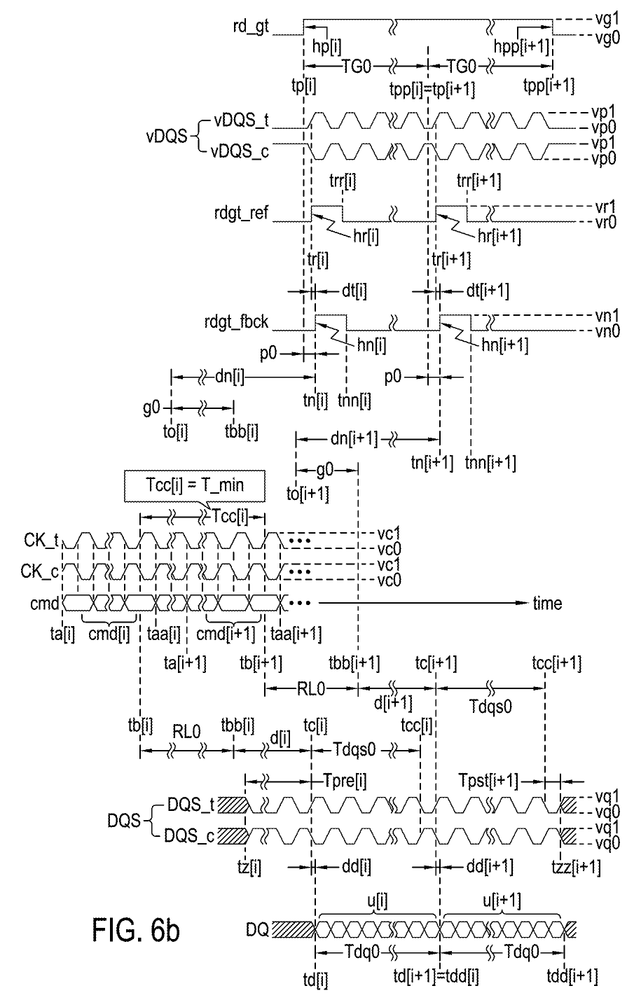

Continuing FIGS. 1, 3b and 3c, 6a and 6b illustrate, by example, waveform and timing embodiments of related signals when the read gating circuit 100 operates in the normal mode. As previously described by referring to FIG. 3b, in FIG. 6a, when the memory 20 responds to the commands cmd[i] and cmd[i+1] with the duration Tcc[i] between the commands cmd[i] and cmd[i+1] being shorter than the duration T_mrg[i], the memory 20 may merge the postamble and the preamble respectively corresponding to the commands cmd[i] and cmd[i+1] in the signals DQS_t and DQS_c, and may, by unambiguous waveforms, form the strobe edges in the signals DQS_t and DQS_c between the time points tz[i] and tzz[i+1]. On the other hand, because the duration Tcc[i] is longer than the duration T_min, the waveform of the signal DQ may be ambiguous between the time points tdd[i] and td[i+1].

As previously described by referring to FIG. 5, in FIG. 6a, corresponding to the command cmd[i], the delay circuit 110 may form the significant edge hn[i] in the signal rdgt_fbck at the time point tn[i], and may form the edges hp[i] and hpp[i] in the signal rd_gt respectively at the time points tp[i] and tpp[i], wherein the delay circuit 110 may determine when the time points tp[i], tn[i] and tpp[i] should be according to the signal s_c. According to the signal rd_gt, the validation-control circuit 120 may select the effective strobe edges from the strobe edges in the signals DQS_t and DQS_c, and may remove ineffective strobe edge(s). To be more specific, the validation-control circuit 120 may, in response to the strobe edges between the time points tp[i] and tpp[i] in the signals DQS_t and DQS_c, form the corresponding strobe edges in the signals vDQS_t and vDQS_c, wherein the strobe edges in the signals vDQS_t and vDQS_c may represent the effective strobe edges in the signals DQS_t and DQS_c. According to the strobe edges in the signal vDQS_t and vDQS_c, the data circuit 50 may sample the signal DQ, and may thereby retrieve the bits of the data burst u[i]. In addition, according to (in response to) the earliest strobe edge in the signals DQS_t and DQS_c that is after the time point tp[i] (i.e., the earliest effective strobe edge formed in the signals DQS_t and DQS_c when the memory 20 responds to the command cmd[i]), the validation-control circuit 120 may form the significant edge hr[i] in the signal rdgt_ref at the time point tr[i]. The detection circuit 130 may detect the time difference dt[i] between the significant edges hn[i] and hr[i], and may reflect corresponding detection result in the signal s_d; the filter circuit 140 may perform signal processing (e.g., filtering operation) on the signal s_d, and may reflect corresponding signal process result in the signal s_c.

Similarly, corresponding to the command cmd[i+1], the delay circuit 110 may cause the signal rdgt_fbck to change from the levels vn0 to vn1 at a time point tn[i+1], and may thereby form a significant edge hn[i+1] in the signal rdgt_fbck; also, the delay circuit 110 may cause the signal rdgt_fbck to change back from the levels vn1 to vn0 at another time point tnn[i+1]. Corresponding to the command cmd[i+1], the delay circuit 110 may further cause the signal rd_gt to change from the levels vg0 to vg1 at a time point tp[i+1], may further cause the signal rd_gt to change back from the levels vg1 to vg0 at another time point tpp[i+1], and may thereby form two edges hp[i+1] and hpp[i+1] in the signal rd_gt. The time point tn[i+1] may be later than a time point to[i+1] by a duration dn[i+1], the time point to[i+1] may be earlier than the time point tbb[i+1] by the duration g0, the time point tp[i+1] may be earlier than the time point tn[i+1] by the duration p0, and the time point tpp[i+1] may be later than the time point tp[i+1] by the duration TG0. For the command cmd[i+1], the time point to[i+1] may be referred to as an origin time point, and may reflect timing of the command cmd[i+1]; the duration dn[i+1] may be controlled by the signal s_c. In an embodiment, the duration dn[i+1] may comprise the duration Tn1 and a duration Tn[i+1] respectively controlled by the signal values s_cr[i] and s_cf[i] of the signal s_c.

According to the signal rd_gt, when the memory 20 forms the strobe edges in the signals DQS_t and DQS_c in response to the command cmd[i+1], the validation-control circuit 120 may select effective strobe edges from the strobe edges of the signals DQS_t and DQS_c, and may remove ineffective strobe edges. For example, the validation-control circuit 120 may, in response to the strobe edges that are between the time points tp[i+1] and tpp[i+1] in the signals DQS_t and DQS_c, form corresponding strobe edges in the signals vDQS_t and vDQS_c. According to the strobe edges in the signals vDQS_t and vDQS_c, the data circuit 50 may sample the signal DQ to retrieve the bits of the data burst u[i+1]. In addition, according to (in response to) to an earliest strobe edge in the signal DQS_t and DQS_c that is after the time point tp[i+1], the validation-control circuit 120 may form a significant edge hr[i+1] (an edge changing from the levels vr0 to vr1) in the signal rdgt_ref at a time point tr[i+1]. The detection circuit 130 may detect a time difference dt[i+1] between the significant edges hn[i+1] and hr[i+1], and may reflect corresponding detection result in the signal s_d; the filter circuit 140 may perform signal process (e.g., filtering process) on the signal s_d, and may reflect corresponding signal process result in the signal s_c.

As shown in FIG. 6a, an interval between the time points to[i+1] and time point tb[i+1] may equal the interval between the time points to[i] and tb[i], and the duration Tcc[i] between the time points tb[i] and tb[i+1] may be an interval between the commands cmd[i] and cmd[i+1]. The time points tc[i] and tc[i+1] may represent actual timing of the effectively strobe edges formed by the memory 20 in response to the commands cmd[i] and cmd[i+1] respectively, and an interval between the time points tc[i] and tc[i+1] may equal (Tcc[i] + d[i+1] - d[i]). On the other hand, each pair of the time points tn[i] and tn[i+1], the time points tp[i] and tp[i+1] and the time points tpp[i] and tpp[i+1] may represent expected timing of the effective strobe edges respectively corresponding to the commands cmd[i] and cmd[i+1], and an interval between the time points tn[i] and tn[i+1], an interval between the time points tp[i] and tp[i+1] and an interval between the time points tpp[i] and tpp[i+1] may equal (Tcc[i] + dn[i+1] - dn[i]). From the above description, it is understood that, as the command cmd[i+1] is closer to the command cmd[i] (as the duration Tcc[i] is shorter), the time points tc[i+1] and time point tc[i] related to the memory 20 may be closer, and the time points tp[i+1] and tp[i], the time points tn[i+1] and tn[i] as well as the time points tpp[i+1] and tpp[i] related to the delay circuit 110 may be closer. In other words, the expected timing of the effective strobe edges estimated by the delay circuit 110 may keep good track of the actual timing of the effective strobe edges, and the validation-control circuit 120 may therefore correctly select the effective strobe edges from the signals DQS_t and DQS_c according to the signal rd_gt from the delay circuit 110 even when the duration Tcc[i] between the commands cmd[i] and cmd[i+1] varies.

In the example of FIG. 6a, the duration Tcc[i] between the commands cmd[i] and cmd[i+1] is shorter than the duration T_mrg[i], so the memory 20 may, when responding to the commands cmd[i] and cmd[i+1], merge the postamble and the preamble respectively corresponding to the commands cmd[i] and cmd[i+1] in the signals DQS_t and DQS_c between the time points tcc[i] and tc[i+1]; the waveforms of the signals DQS_t and DQS_c may therefore be unambiguous between the time points tcc[i] and tc[i+1], and may possibly include one or more ineffective strobe edges. However, as shown in FIG. 6a, even though the memory 20 merges the postamble corresponding to the command cmd[i] and the preamble corresponding to the command cmd[i+1] in the example of FIG. 6a, the delay circuit 110 may still form the edges hpp[i] and hp[i+1] in the signal rd_gt; thus, when the validation-control circuit 120 operates according to the signal rd_gt, the validation-control circuit 120 may remove the ineffectively strobe edge(s) possibly existing between the time points tcc[i] and tc[i+1]. As shown in FIG. 6a, in an embodiment, the validation-control circuit 120 may keep the signals vDQS_t and vDQS_c at the levels vp0 and vp1 between the time points tpp[i] and tp[i+1] of the edges hpp[i] and hp[i+1], so there may not be any strobe edge in the signals vDQS_t and vDQS_c between the time points tpp[i] and tp[i+1].

In the example of FIG. 6b, the duration Tcc[i] between the commands cmd[i] and cmd[i+1] equals the duration T_min, so the memory 20 may, when responding to the commands cmd[i] and cmd[i+1], seamlessly join the data bursts u[i] and u[i+1] in the signal DQ, and may also remove the postamble and the preamble respectively corresponding to the commands cmd[i] and cmd[i+1] from the signals DQS_t and DQS_c; the signals DQS_t and DQS_c may therefore not include any ineffective strobe edge between the time points tc[i] and tcc[i+1]. However, as shown in FIG. 6b, if the duration Tcc[i] between the commands cmd[i] and cmd[i+1] equals the duration T_min, the time point tpp[i] corresponding to the command cmd[i] and the time point tp[i+1] corresponding to the command cmd[i+1] may coincide (or the time point tpp[i] may be later than the time point tp[i+1]); the delay circuit 110 may therefore cancel the edges hpp[i] and hp[i+1] respectively at the time points tpp[i] and tp[i+1] in the signal rd_gt, and may thereby cause the signal rd_gt to remain at the level vg1 between the time points tp[i] and tpp[i+1]. Thus, when the validation-control circuit 120 operates according to the signal rd_gt, the validation-control circuit 120 may select the strobe edges that are between the time points tp[i] and tpp[i+1] in the signals DQS_t and DQS_c as gated strobe edges, and may reflect the selected strobe edges in the signals vDQS_t and vDQS_c. Hence, when the data circuit 50 samples the signal DQ according to the strobe edges in the signals vDQS_t and vDQS_c, the data circuit 50 may correctly retrieve the bits of the seamlessly joined data bursts u[i] and u[i+1].

As shown in FIG. 3a, if the duration Tcc[i] between the commands cmd[i] and cmd[i+1] is longer than the duration T_mrg[i], the memory 20 may, when responding to the commands cmd[i] and cmd[i+1], not merge the postamble and the preamble respectively corresponding to the commands cmd[i] and cmd[i+1]; i.e., the memory 20 may form complete preamble and postamble in the signals DQS_t and DQS_c when responding command cmd[i], and may also form complete preamble and postamble in the signals DQS_t and DQS_c when responding to the command cmd[i+1]. For the example shown in FIG. 3a, operations of the delay circuit 110 and the validation-control circuit 120 may be understood according to the description related to FIGS. 5 and 6a. Corresponding to the commands cmd[i] and cmd[i+1], the delay circuit 110 may sequentially form the edges hp[i], hpp[i], hp[i+1] and hpp[i+1] in the signal rd_gt at the time points tp[i], tpp[i], tp[i+1] and tpp[i+1] respectively, wherein time point tpp[i] may be earlier than the time point tp[i+1] by an interval which may reflect (e.g., may positively correlate to) an interval between the time points tcc[i] and tc[i+1]. Thus, when validation-control circuit 120 operates according to the signal rd_gt, the validation-control circuit 120 may, according to the edges hpp[i] and hp[i+1] of the signal rd_gt, remove the postamble (between the time points tcc[i] and tzz[i], FIG. 3a) corresponding to the command cmd[i] and the preamble (between the time points tz[i+1] and tc[i+1], FIG. 3a) corresponding to the command cmd[i+1]. For example, the validation-control circuit 120 may cause the signals vDQS_t and vDQS_c to respectively remain at the levels vp0 and vp1 between the time points tpp[i] and tp[i+1] of the edges hpp[i] and hp[i+1], such that the signals vDQS_t and vDQS_c may not include strobe edge(s) between the time points tpp[i] and tp[i+1].

To sum up, a physical layer circuit (e.g., 10) according to the present disclosure may access a memory (e.g., 20), and may comprise a read gating circuit (e.g., 100); the read gating circuit may improve read gating when reading the memory. In an embodiment, the read gating circuit according to the present disclosure may comprise a delay circuit (e.g., 110), a validation-control circuit (e.g., 120) and a detection circuit (e.g., 130). In a training mode (e.g., FIG. 4a), when the memory forms a plurality of first strobe edges (e.g., the strobe edges between the time points tc1 and tcc1) in a strobe signal (e.g., DQS_t and DQS_c) in response to a first command (e.g., cmd1), the delay circuit may reflect expected timing of the first strobe edges by a first internal duration (e.g., dn1), and may reflect the first internal duration by an internal signal (e.g., rdgt_fbck), e.g., may form a first internal edge (e.g., hn1) in the internal signal according to the first internal; the validation-control circuit may reflect actual timing of the first strobe edges by a reference signal (e.g., rdgt_ref), e.g., may form a first reference edge (e.g., hr1) in the reference signal according to (in response to) an earliest one of the first strobe edges; the detection circuit may detect timing difference between the internal signal and the reference signal, and may cause a control signal (e.g., s_c) to reflect the detected timing difference, e.g., the detection circuit may detect a first time difference (e.g., dt1) between the first internal edge and the first reference edge, and may cause the control signal to reflect the first time difference.

In the training mode (e.g., FIG. 4b), when the memory forms a plurality of second strobe edges (e.g., the strobe edges between the time points tc2 and tcc2) in response to a second command (e.g., cmd2), the delay circuit may determine a second internal duration (e.g., dn2) according to the control signal to reflect expected timing of the second strobe edges, and may reflect the second internal duration by the internal signal, e.g., may form a second internal edge (e.g., hn2) in the internal signal according to the second internal duration; the validation-control circuit may reflect actual timing of the second strobe edges by the reference signal, e.g., may form a second reference edge (e.g., hr2) in the reference signal according to (in response to) an earliest one of the second strobe edges; the detection circuit may detect timing difference between the internal signal and the reference signal, e.g., may detect a second time difference (e.g., dt2) between the second internal edge and the second reference edge. In an embodiment, the detection circuit may count a number of interface clock periods (e.g., T0) within the first time difference when detecting the first time difference, and may cause the control signal to reflect a coarse tuning number (e.g., Nk1) resulting from the counting; when the delay circuit determines the second internal duration according to the control signal, the delay circuit may determine the second internal duration according to the first internal duration and the coarse tuning number, and may thereby cause the second time difference to be far shorter than the first time difference, e.g., may cause a multiple of the second time difference to be less than the first time difference. In other words, the present disclosure may rapidly (e.g., during the two commands cmd1 and cmd2) lock expected timing of the strobe edges onto actual timing of the strobe edges.

In a normal mode (e.g., FIG. 5), when the memory, in response to a third command (e.g., cmd[i]), forms a plurality of third strobe edges (e.g., the strobe edges between the time points tz[i] and tzz[i]) in the strobe signal (e.g., DQS_t and DQS_c) and provides a data burst (e.g., u[i]) in a data signal (e.g., DQ), the delay circuit may determine a third internal duration (e.g., dn[i]) according to the control signal to reflect expected timing of effective strobe edges among the third strobe edges, and may reflect the third internal duration by the internal signal and a gating signal (e.g., rd_gt), e.g., may form a third internal edge (e.g., hn[i]) in the internal signal according to the third internal duration, and may form a front gating edge (e.g., hp[i]) and a back gating edge (e.g., hpp[i]) in the gating signal according to the third internal duration; the validation-control circuit may reflect timing of the gating signal by a gated strobe signal (e.g., vDQS_t and vDQS_c) and the reference signal, e.g., may reflect third strobe edges that are between the front gating edge and the back gating edge by corresponding strobe edges in the gated strobe signal, and may form a third reference edge (e.g., hr[i]) in the reference signal according to (in response to) an earliest third strobe edge occurring after the front gating edge; a data circuit (e.g., 50) in the physical layer circuit may sample the data signal according to the gated strobe signal to retrieve each binary bit of the data burst, the detection circuit may detect timing difference between the internal signal and the reference signal, and may cause the control signal to reflect the detected timing difference, e.g., may detect a third time difference (e.g., dt[i]) between the third internal edge and the third reference edge, and may cause the control signal to reflect the third time difference. In an embodiment, the third internal duration may comprise a coarse tuning duration (e.g., Tn1) and a fine tuning duration (e.g., Tn[i]), wherein the coarse tuning duration may equal the coarse tuning number times the interface clock period, and the fine tuning duration may be shorter than the interface clock period. In other words, based on the lock achieved in the training mode, the present disclosure may continue to lock timing of effective strobe edges in the normal mode, and may thereby correctly retrieve each bit of the data burst from the data signal.

In the normal mode (e.g., FIGS. 6a and 6b), when the memory, in response to a third command (e.g., cmd[i]) and a consecutive fourth command (e.g., cmd[i+1]), forms a plurality of responding strobe edges (e.g., the strobe edges between the time points tz[i] and tzz[i+1]) in the strobe signal (e.g., DQS_t and DQS_c) and provides two data bursts (e.g., u[i] and u[i+1]) in the data signal, the delay circuit may determine a third internal duration (e.g., dn[i]) and a fourth internal duration (e.g., dn[i+1]) according to the control signal to reflect expected timing of effective strobe edges among the responding strobe edges, and may reflect the third internal duration and the fourth internal duration by the internal signal, e.g., may form a third internal edge (e.g., hn[i]) and a fourth internal edge (e.g., hn[i+1]) in the internal signal respectively according to the third internal duration and the fourth internal duration. The delay circuit may further reflect the third internal duration and the fourth internal duration by the gating signal, e.g., if an interval between the third command and the fourth command is longer than a minimal interval (e.g., T_min in FIG. 6a), the delay circuit may form a third front gating edge (e.g., hp[i]) and a third back gating edge (e.g., hpp[i] in FIG. 6a) in the gating signal according to the third internal duration, and may form a fourth front gating edge (e.g., hp[i+1] in FIG. 6a) and a fourth back gating edge (e.g., hpp[i+1]) in the gating signal according to the fourth internal duration; if the interval between the third command and the fourth command is not greater than (e.g., equals) the minimal interval, the delay circuit may form a common front gating edge (e.g., hp[i] in FIG. 6b) and a common back gating edge (e.g., hpp[i+1] in FIG. 6b) in the gating signal according to the third internal duration. The validation-control circuit may reflect timing of the gating signal by the gated strobe signal and the reference signal, e.g., may reflect responding strobe edges that are between the common front gating edge and the common back gating edge by corresponding strobe edges in the gated strobe signal, and may form a third reference edge (e.g., hr[i]) and a fourth reference edge (e.g., hr[i+1]) in the reference signal according to (in response to) an earliest responding strobe edge occurring after the common front gating edge; the data circuit (e.g., 50) may sample the data signal according to the gated strobe signal to retrieve each binary bit of the two data bursts, the detection circuit may detect timing difference between the internal signal and the reference signal, and may cause the control signal to reflect the detected timing difference, e.g., may detect a third time difference (e.g., dt[i]) between the third internal edge and the third reference edge, as well as a fourth time difference (e.g., dt[i+1]) between the fourth internal edge and the fourth reference edge, and may cause the control signal to reflect the third time difference and the fourth time difference. In other words, regardless of whether an interval between two consecutive commands equals the minimal interval, the present disclosure may adaptively cause the gated strobe signal to correctly reflect the effective strobe edges.

While the present disclosure has been described in terms with reference to several embodiments, it is to be understood that the present disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A physical layer circuit coupled to a memory, comprising:
a delay circuit, a validation-control circuit and a detection circuit, wherein:
the validation-control circuit is coupled to the delay circuit and a strobe signal;
the detection circuit is coupled to the delay circuit and the validation-control circuit;
in a first mode, the physical layer circuit is configured to transmit a first command to the memory, such that the memory sequentially forms a plurality of first strobe edges in the strobe signal in response to the first command;
the validation-control circuit is configured to form a first reference edge in a reference signal in response to an earliest one of the first strobe edges;
the delay circuit is configured to, corresponding to the first command, form a first internal edge in an internal signal;
the detection circuit is configured to detect a first time difference between the first internal edge and the first reference edge, and to cause a control signal to reflect a detection result of the first time difference;
in the first mode, the physical layer circuit is further configured to transmit a second command to the memory, such that the memory further sequentially forms a plurality of second strobe edges in the strobe signal in response to the second command;
the validation-control circuit is further configured to form a second reference edge in the reference signal in response to an earliest one of the second strobe edges; and
the delay circuit is further configured to, corresponding to the second command, form a second internal edge in the internal signal according to the control signal, and to thereby cause a second time difference between the second internal edge and the second reference edge to be shorter than the first time difference.

2. The physical layer circuit of claim 1, wherein:
the delay circuit is configured to cause the second time difference to be shorter than the first time difference by causing a multiple of the second time difference to be less than the first time difference.

3. The physical layer circuit of claim 1, wherein:
the first time difference is greater than a multiple of an interface clock period; and
the delay circuit is configured to cause the second time difference to be shorter than the first time difference by causing the second time difference to be shorter than the interface clock period.

4. The physical layer circuit of claim 1, wherein:
in a second mode, the physical layer circuit is further configured to transmit a third command to the memory, such that the memory further sequentially forms a plurality third strobe edges in the strobe signal in response to the third command, and the memory further provides a third data burst in a data signal in response to the third command;
the delay circuit is further configured to, corresponding to the third command, form a front gating edge and a back gating edge in a gating signal according to the control signal;
the validation-control circuit is further configured to select, according to the gating signal, one or more of the third strobe edges that are between the front gating edge and the back gating edge, and to reflect a selection result of the third strobe edges in a gated strobe signal;
the physical layer circuit further comprises a data circuit;
the data circuit is coupled to the validation-control circuit; and
the data circuit is configured to sample the data signal according to the gated strobe signal to retrieve the third data burst.

5. The physical layer circuit of claim 4, wherein:
the delay circuit is further configured to, corresponding to the third command, form a third internal edge in the internal signal according to the control signal;
the validation-control circuit is further configured to form a third reference edge in the reference signal according to the selection result;
the detection circuit is further configured to detect a third time difference between the third internal edge and the third reference edge, and to cause the control signal to reflect a detection result of the third time difference;
the front gating edge occurs before the third internal edge; and
the back gating edge occurs after the third internal edge.

6. The physical layer circuit of claim 1, wherein:
in a second mode, the physical layer circuit is further configured to transmit a third command to the memory, such that the memory further sequentially forms a plurality of third strobe edges in the strobe signal in response to the third command;
the delay circuit is further configured to, corresponding to the third command, form a third internal edge in the internal signal according to the control signal, and form a front gating edge in a gating signal according to the control signal;
the validation-control circuit is further configured to form a third reference edge in the reference signal in response to one of the third strobe edges that occurs earliest after the front gating edge; and
the detection circuit is further configured to detect a third time difference between the third internal edge and the third reference edge, and to cause the control signal to reflect a detection result of the third time difference.

7. The physical layer circuit of claim 6, wherein the detection circuit is configured to generate a detection signal by detecting the third time difference, and the detection signal reflects the detection result of the third time difference; the physical layer circuit further comprises:
a filter circuit, coupled between the detection circuit and the delay circuit, the filter circuit being configured to perform filtering operation on the detection signal to generate the control signal.

8. The physical layer circuit of claim 6, wherein:
the delay circuit is configured to form the third internal edge at a third internal edge time point;
the third internal edge time point is later than a third origin time point, and an interval between the third origin time point and the third internal edge time point comprises a coarse tuning duration and a fine tuning duration;
the coarse tuning duration is a multiple of an interface clock period; and
the fine tuning duration is shorter than the interface clock period.

9. The physical layer circuit of claim 8, wherein:
the coarse tuning duration substantially equals the first time difference minus the second time difference.

10. The physical layer circuit of claim 6, wherein:
the control signal comprises a coarse tuning signal and a fine tuning signal;
the delay circuit is configured to wait for a coarse tuning duration and a fine tuning duration according to the coarse tuning signal and the fine tuning signal, respectively, and form the third internal edge at a third internal edge time point after the coarse tuning duration and the fine tuning duration have elapsed.

11. The physical layer circuit of claim 10, wherein:
the delay circuit comprises a counter;
the coarse tuning signal reflects a coarse tuning number; and
the delay circuit is configured to wait for the coarse tuning duration by using the counter to count the coarse tuning number of interface clock periods.

12. The physical layer circuit of claim 11, wherein:
the coarse tuning number relates to the first time difference.

13. The physical layer circuit of claim 10, wherein:
the delay circuit comprises a controlled delay line;
the delay circuit is configured to wait for the fine tuning duration by using the controlled delay line to wait for the fine tuning duration; and
the fine tuning duration is controlled by the fine tuning signal.

14. The physical layer circuit of claim 6, wherein:
operation of the detection circuit for detecting the third time difference between the third internal edge and the third reference edge comprises determining whether the third internal edge occurs before or after the third reference edge.

15. The physical layer circuit of claim 1, wherein:
operation of the detection circuit for detecting the first time difference and causing the control signal to reflect the detection result comprises: counting a number of interface clock periods within the first time difference, and causing the control signal to reflect a result of the counting.

16. The physical layer circuit of claim 1, wherein:
in a second mode, the physical layer circuit is further configured to sequentially transmits a third command and a fourth command to the memory, such that the memory further sequentially forms a plurality of responding strobe edges in the strobe signal in response to the third command and the fourth command, and the memory further provides a third data burst and a fourth data burst in a data signal in response to the third command and the fourth command, respectively;
the delay circuit is further configured to, when an interval between the third command and the fourth command is greater than a minimal interval, form a third front gating edge, a third back gating edge, a fourth front gating edge and a fourth back gating edge in a gating signal according to the control signal;
the validation-control circuit is further configured to select one or more third gated strobe edges and one or more fourth gated strobe edges from the responding strobe edges according to the gating signal;
each of the one or more third gated strobe edges is one of the responding strobe edges, and occurs between the third front gating edge and the third back gating edge;
each of the one or more fourth gated strobe edges is one of the responding strobe edges, and occurs between the fourth front gating edge and the fourth back gating edge;
the physical layer circuit further comprises a data circuit coupled to the validation-control circuit; and
the data circuit is configured to sample the data signal according to the one or more third gated strobe edges to retrieve the third data burst, and is configured to sample the data signal according to the one or more fourth gated strobe edges to retrieve the fourth data burst.

17. The physical layer circuit of claim 1, wherein:
in a second mode, the physical layer circuit is further configured to sequentially transmit a third command and a fourth command to the memory, such that the memory further sequentially forms a plurality of responding strobe edges in the strobe signal in response to the third command and the fourth command, and the memory further provides a third data burst and a fourth data burst in a data signal in response to the third command and the fourth command, respectively;
the delay circuit is further configured to, when an interval between the third command and the fourth command is not greater than a minimal interval, form a common front gating edge and a common back gating edge in a gating signal according to the control signal;
the validation-control circuit is further configured to select one or more gated strobe edges from the responding strobe edges according to the gating signal;
each of the one or more gated strobe edges is one of the responding strobe edges, and occurs between the common front gating edge and the common back gating edge;
the physical layer circuit further comprises a data circuit coupled to the validation-control circuit; and
the data circuit is configured to sample the data signal according to the one or more gated strobe edges to retrieve the third data burst and the fourth data burst.

18. A physical layer circuit coupled to a memory, comprising:
a delay circuit, a validation-control circuit and a detection circuit, wherein:
the validation-control circuit is coupled to the delay circuit and a strobe signal;
the detection circuit is coupled to the delay circuit and the validation-control circuit;
the physical layer circuit is configured to transmit a command to the memory, such that the memory sequentially forms a plurality of strobe edges in the strobe signal in response to the command;
the delay circuit is configured to, corresponding to the command, form an internal edge in an internal signal;
in a first mode, the validation-control circuit is configured to form a reference edge in a reference signal in response to an earliest one of the strobe edges;
in a second mode, the delay circuit is further configured to form a front gating edge in a gating signal;
in the second mode, the validation-control circuit is configured to form the reference edge in the reference signal in response to one of the strobe edges that occurs earliest after the front gating edge, wherein the front gating edge occurs earlier than the internal edge; and
the detection circuit is configured to detect a time difference between the internal edge and the reference edge, and to reflect a detection result of the time difference in a detection signal.

19. The physical layer circuit of claim 18, wherein:
the physical layer circuit further comprises a filter circuit coupled between the detection circuit and the delay circuit;
the filter circuit is configured to perform filtering operation on the detection signal to provide a control signal; and
the delay circuit is configured to determine, according to the control signal, a time at which the internal edge in the internal signal is formed.

20. The physical layer circuit of claim 18, wherein:
the delay circuit is configured to wait for a coarse tuning duration and a fine tuning duration, and form the internal edge at an internal edge time point after the coarse tuning duration and the fine tuning duration have elapsed;
the coarse tuning duration is an integer multiple of an interface clock period; and
the fine tuning duration is shorter than the interface clock period.
